(19) United States
(12) Patent Application Publication
(10) Pub. No.: US 2026/0020339 A1
(43) Pub. Date: Jan. 15, 2026

(54) SEMICONDUCTOR DEVICE

(71) Applicant: Taiwan Semiconductor Manufacturing Company, Ltd., Hsinchu (TW)

(72) Inventor: Jhon-Jhy Liaw, Zhudong Township (TW)

(73) Assignee: Taiwan Semiconductor Manufacturing Company, Ltd., Hsinchu (TW)

(21) Appl. No.: 18/771,416

(22) Filed: Jul. 12, 2024

(51) Int. Cl. H01L 27/118; H03K 19/20

(52) U.S. Cl. CPC H10D 84/907; H03K 19/20; H10D 84/929; H10D 84/953

(57) ABSTRACT

A semiconductor device includes a first circuit cell, a first dielectric layer, a second dielectric layer, and a third dielectric layer. The first circuit cell includes a first active area in a first well in a substrate, a second active area in a second well in the substrate, and a first gate structure wrapping around nanostructures in the first active area and the second active area. The first dielectric layer is over the first well. The second dielectric layer is over the first well and the second well. The third dielectric layer is over the second well. The first dielectric layer, the second dielectric layer, and the third dielectric layer are under and in contact with the first gate structure. A thickness of the second dielectric layer is less than thicknesses of the first dielectric layer and the third dielectric layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been incorporated into memory devices (including, for example, static random-access memory, or SRAM, cells) and core devices (including, for example, standard logic, or STD, cells) to reduce chip footprint while maintaining reasonable processing margins.

However, as GAA transistors and circuit cells continue to be scaled down, existing active area space and gate structure shape impact the source/drain feature bridge margin as well as performance. Accordingly, although existing technologies for fabricating circuit cells including GAA transistors have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIGS. 2A, 2B, 2C, 2D, and 2E illustrate circuit schematics of various STD cells in the array of circuit cells in the logic region of the IC chip, in accordance with some embodiments of the present disclosure.

FIG. 3 illustrates a perspective view of an embodiment of a GAA transistor in the array of circuit cells, in accordance with some embodiments of the present disclosure.

FIG. 4A illustrates a top view (or a layout) of a semiconductor device of an array of the circuit cells in the logic region of the IC chip, in accordance with some embodiments of the present disclosure.

FIG. 4B illustrates a Y-Z cross-sectional view of the semiconductor device along a line A-A′ of FIG. 4A, respectively, in accordance with some embodiments of the present disclosure.

FIG. 4C illustrates an X-Z cross-sectional view of the semiconductor device along a line B-B′ of FIG. 4A, respectively, in accordance with some embodiments of the present disclosure.

FIG. 4D illustrates an X-Z cross-sectional view of the semiconductor device along a line C-C′ of FIG. 4A, respectively, in accordance with some embodiments of the present disclosure.

FIG. 5A illustrates an X-Z cross-sectional view of the semiconductor device along a line B-B′ of FIG. 4A, respectively, in accordance with some alternative embodiments of the present disclosure.

FIG. 5B illustrates an X-Z cross-sectional view of the semiconductor device along a line C-C′ of FIG. 4A, respectively, in accordance with some alternative embodiments of the present disclosure.

FIG. 6 illustrates a partial enlarged cross-sectional view of the semiconductor device of FIG. 4B, in accordance with some embodiments of the present disclosure.

FIG. 7 illustrates a perspective view of a workpiece at a fabrication stage for the semiconductor device, in accordance with some embodiments of the present disclosure.

FIGS. 8A, 9A, 10A, 11A, 12A, 13A, 14A, 15A, 16A, and 17A illustrate Y-Z cross-sectional views of the workpiece at various fabrication stage along a line C-C′ of FIG. 7, respectively, in accordance with some embodiments of the present disclosure.

FIGS. 8B, 9B, 10B, 11B, 12B, 13B, 14B, 15B, 16B, and 17B illustrate X-Z cross-sectional views of the workpiece at various fabrication stage along a line D-D′ of FIG. 7, respectively, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors, in memory (e.g., SRAM) and/or standard logic cells of an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications. While existing technologies for fabricating GAA transistors have been generally adequate for their intended applications, they have not been entirely satisfactory in all aspects.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and devices including reduced active area space and different isolation structure thicknesses for circuit cells, such that the process margin and performance are improved. The details of the devices and manufacturing methods of the present disclosure are described below in conjunction with the accompanying drawings, which illustrate the process of making GAA transistors, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

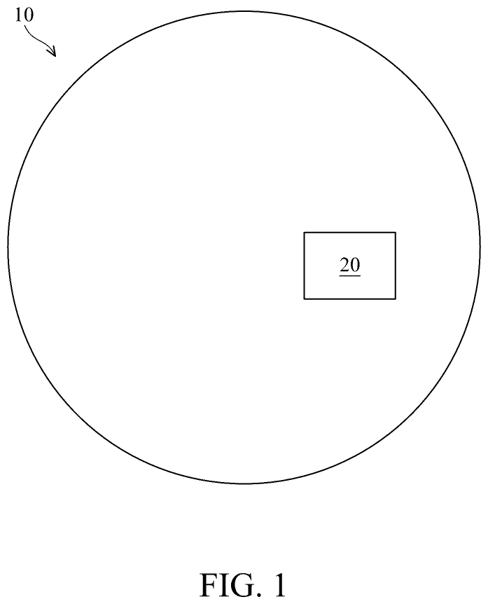

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, P-type field effect transistors (PFETs), N-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or combinations thereof. The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. As shown in FIG. 1, the IC chip 10 includes a logic region 20. The logic region 20 may include an array of circuit cells having various logic cells or standard (STD) cells. The logic cells or STD cells may include transistors and interconnect structures that combine to provide a logic device and/or a logic function, such as an inverter, an AND, an NAND, an OR, an NOR, a NOT, an XOR, an XNOR, a Flip-Flop, other suitable logic devices, or combinations thereof. FIG. 1 has been simplified for the sake of clarity to better understand the inventive concepts of the present disclosure. Additional features can be added in the IC chip 10, and some of the features described herein can be replaced, modified, or eliminated in other embodiments of the IC chip 10.

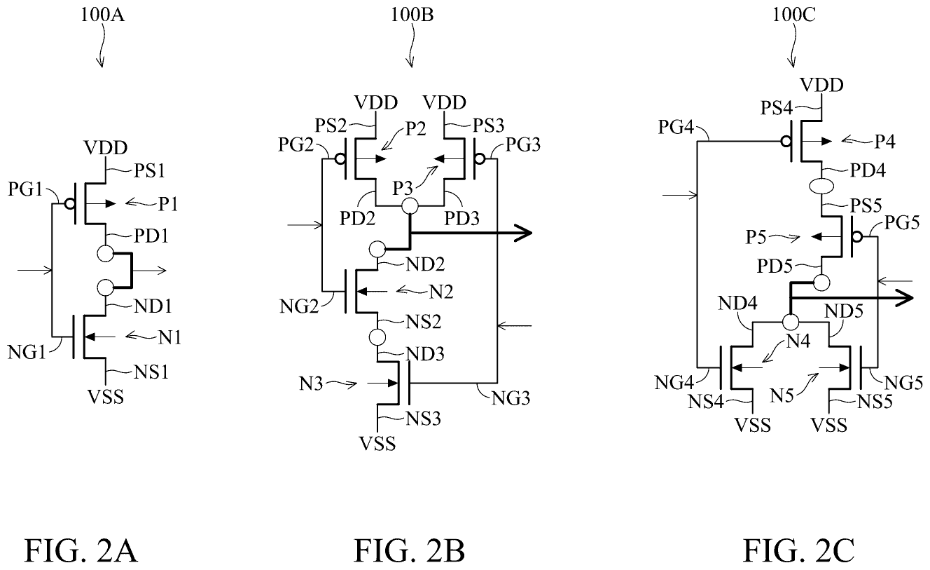

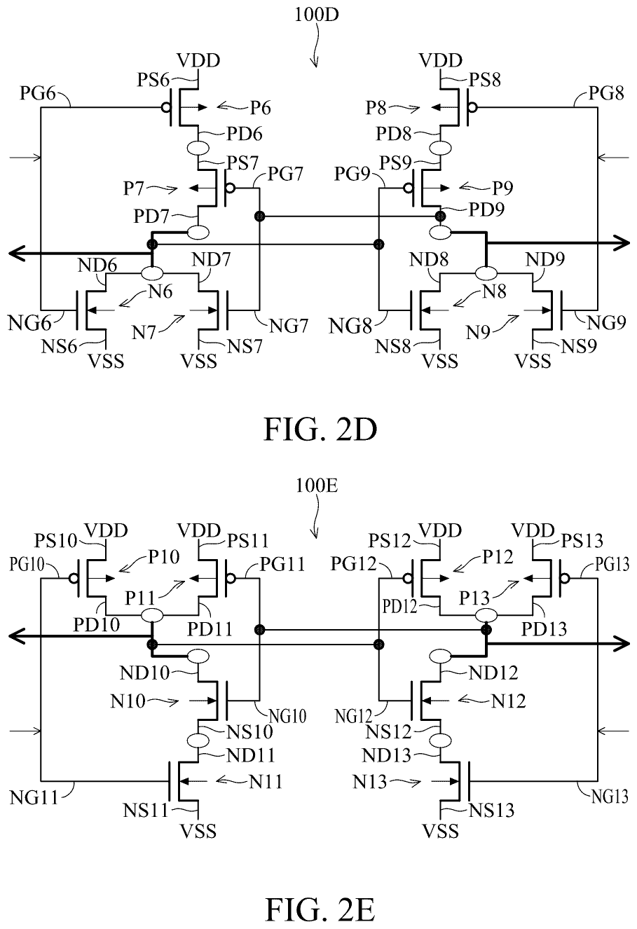

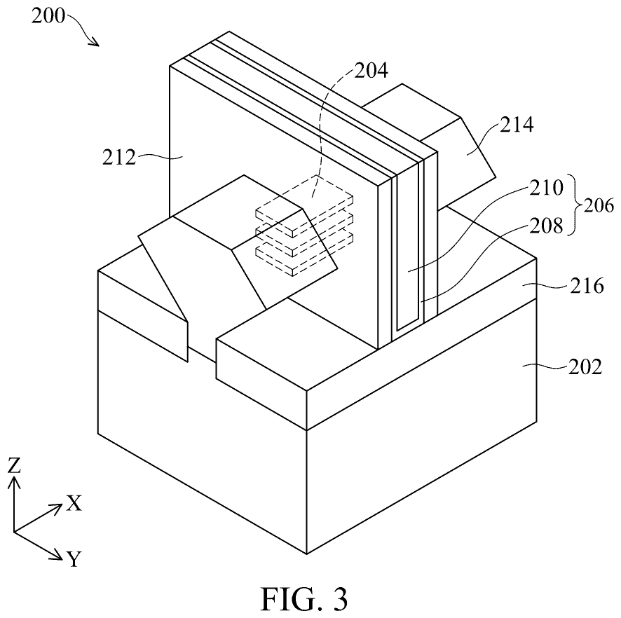

FIGS. 2A to 2E are circuit schematics of various STD cells in the array of circuit cells in the logic region 20 of the IC chip 10, in accordance with some embodiments of the present disclosure.

FIG. 2A shows an inverter 100A including an N-type transistor N1 and a P-type transistor P1. The N-type transistor N1 includes a source terminal NS1, a drain terminal ND1, and a gate terminal NG1, and the P-type transistor P1 includes a source terminal PS1, a drain terminal PD1, and a gate terminal PG1.

As shown in FIG. 2A, the gate terminals NGland PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 2B shows a NAND (also referred to as a NAND logic gate, a NAND device or a NAND cell) 100B including N-type transistors N2, N3 and P-type transistors P2, P3. The N-type transistor N2 includes a source terminal NS2, a drain terminal ND2, and a gate terminal NG2, and the N-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 2B, the gate terminals NG2 and PG2 are coupled with each other to operate as a first input terminal of the NAND 100B, and the gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as a “common drain.” The source terminals PS2 and PS3 are coupled to the VDD voltage. The source terminal NS3 is coupled to VSS voltage (or a ground voltage). The source terminal NS2 and drain terminal ND3 are coupled with each other.

FIG. 2C shows a NOR (also referred to as a NOR logic gate, a NOR device or a NOR cell) 100C including N-type transistors N4, N5 and P-type transistors P4, P5. The N-type transistor N4 includes a source terminal NS4, a drain terminal ND4, and a gate terminal NG4, and the N-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 2C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as “common drain.” The source terminal PS4 is coupled to the VDD voltage. The source terminals NS4 and NS5 are coupled to VSS voltage (or a ground voltage). The source terminal PS5 and drain terminal PD4 are coupled with each other.

FIG. 2D shows a flip-flop (also referred to as a flip-flop device or a flip-flop cell) 100D including N-type transistors N6, N7, N8, N9 and P-type transistors P6, P7, P8, P9. The N-type transistor N6 includes a source terminal NS6, a drain terminal ND6, and a gate terminal NG6; the N-type transistor N7 includes a source terminal NS7, a drain terminal ND7, and a gate terminal NG7; the N-type transistor N8 includes a source terminal NS8, a drain terminal ND8, and a gate terminal NG8; and the N-type transistor N9 includes a source terminal NS9, a drain terminal ND9, and a gate terminal NG9. The P-type transistor P6 includes a source terminal PS6, a drain terminal PD6, and a gate terminal PG6; the P-type transistor P7 includes a source terminal PS7, a drain terminal PD7, and a gate terminal PG7; the P-type transistor P8 includes a source terminal PS8, a drain terminal PD8, and a gate terminal PG8; and the P-type transistor P9 includes a source terminal PS9, a drain terminal PD9, and a gate terminal PG9.

As shown in FIG. 2D, the flip-flop 100D is a set-reset (SR) NOR latch. The NOR latch may include a pair of cross-coupled NOR. Specifically, the output terminal of a first NOR is coupled to the second input terminal of a second NOR, and the output terminal of the second NOR is coupled to the second input terminal of the first NOR. The details of the other connections of the flip-flop 100D are similar to the NOR 100C, and may not be described in detail herein.

FIG. 2E shows a flip-flop 100E including N-type transistors N10, N11, N12, N13 and P-type transistors P10, P11, P12, P13. The N-type transistor N10 includes a source terminal NS10, a drain terminal ND10, and a gate terminal NG10; the N-type transistor N11 includes a source terminal NS11, a drain terminal ND11, and a gate terminal NG11; the N-type transistor N12 includes a source terminal NS12, a drain terminal ND12, and a gate terminal NG12; and the N-type transistor N13 includes a source terminal NS13, a drain terminal ND13, and a gate terminal NG13. The P-type transistor P10 includes a source terminal PS10, a drain terminal PD10, and a gate terminal PG10; the P-type transistor P11 includes a source terminal PS11, a drain terminal PD11, and a gate terminal PG11; the P-type transistor P12 includes a source terminal PS12, a drain terminal PD12, and a gate terminal PG12; and the P-type transistor P13 includes a source terminal PS13, a drain terminal PD13, and a gate terminal PG13.

As shown in FIG. 2E, the flip-flop 100E is a SR NAND latch. The NAND latch may include a pair of cross-coupled NAND. Specifically, the output terminal of a first NAND is coupled to the first input terminal of a second NAND, and the output terminal of the second NAND is coupled to the first input terminal of the first NAND. The details of the other connections of the flip-flop 100E are similar to the NAND 100B, and may not be described in detail herein.

Each of the circuit cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, an exemplary GAA transistor is illustrated in FIG. 3. However, it should be understood that the application should not be limited to a particular type of device, except as specifically claimed.

Referring to FIG. 3, a perspective view of an exemplary GAA transistor 200 is illustrated. The GAA transistor 200 is formed over a substrate 202. The substrate 202 may contains a semiconductor material, such as bulk silicon (Si). The GAA transistor 200 also includes one or more nanostructures 204 (dash lines) extending in the X-direction and vertically stacked (or arranged) in the Z-direction. More specifically, the nanostructures 204 are spaced apart from each other in the Z-direction. In some embodiments, the nanostructures 204 may also be referred to as channels, channel layers, nanosheets, or nanowires.

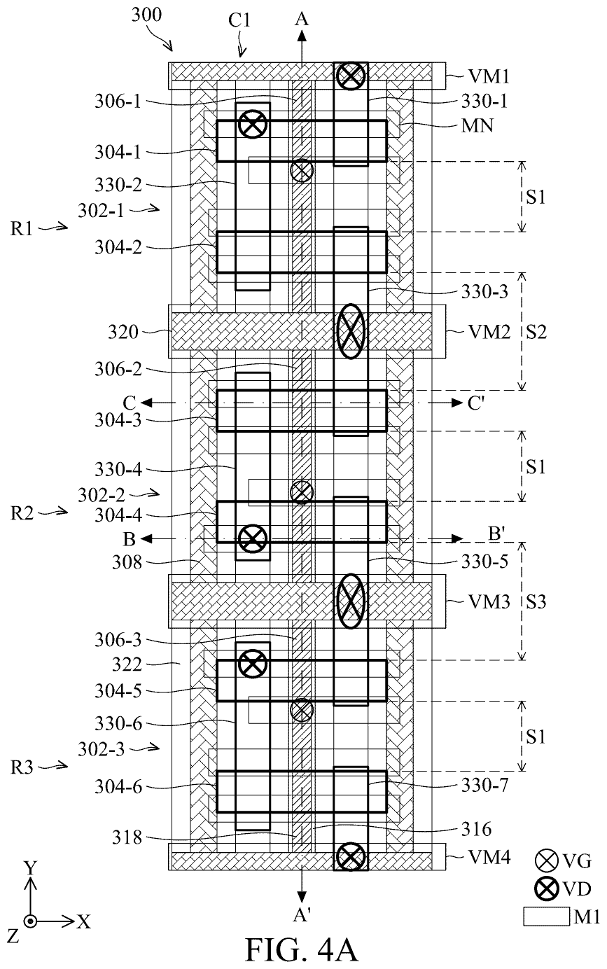

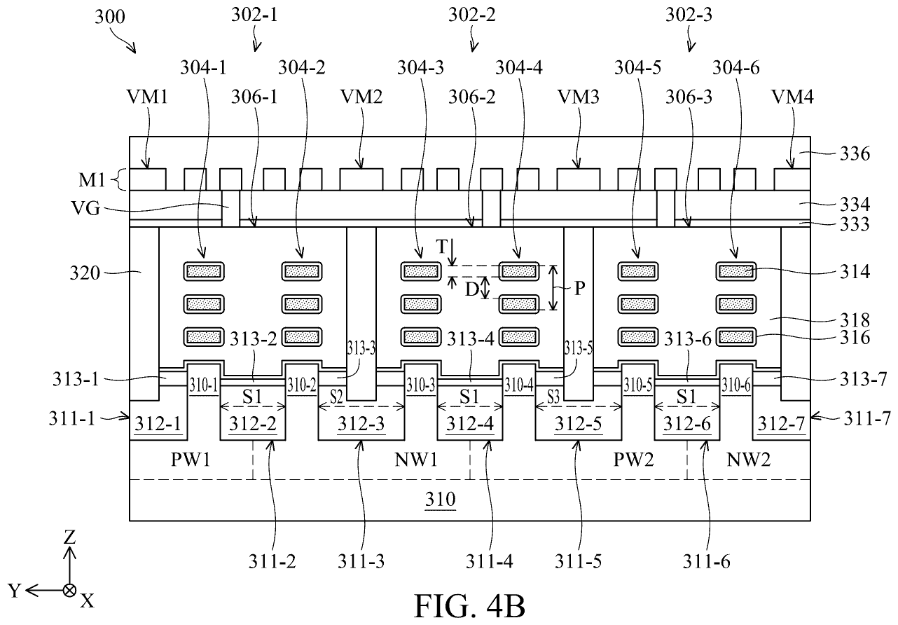

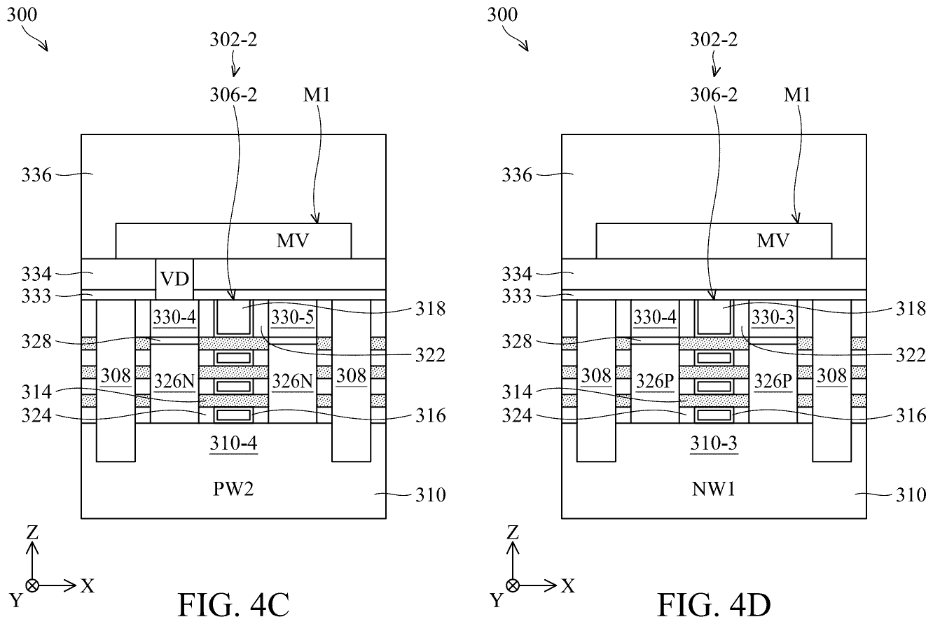

The GAA transistor 200 further includes a gate structure 206 including a gate dielectric layer 208 and a gate electrode 210. The gate dielectric layer 208 wraps around the nanostructures 204 and the gate electrode 210 wraps around the gate dielectric layer 208 (not shown in FIG. 2, may refer to FIGS. 4C, 4D, and 4E). As shown in FIG. 2, gate spacers 212 are on sidewalls of the gate structure 206 and over the nanostructures 204 (not shown in FIG. 2, may refer to FIGS. 4C and 4D)

The GAA transistor 200 further includes source/drain features 214. As shown in FIG. 2, two source/drain features 214 are on opposite sides of the gate structure 206. The nanostructures 204 (dash lines) extend in the X-direction to connect one source/drain feature 214 to the other source/drain feature 214. The source/drain features 214 may also be referred to as source/drain, or source/drain regions. In some embodiments, source/drain feature(s) may refer to a source or a drain, individually or collectively dependent upon the context.

Isolation feature 216 is over the substrate 202 and under the gate dielectric layer 208, the gate electrode 210, and the gate spacers 212. The isolation feature 216 is used for isolating the GAA transistor 200 from other devices. In some embodiments, the isolation feature 216 may include different structures, such as shallow trench isolation (STI) structure, deep trench isolation (DTI) structure. Therefore, the isolation feature 216 is also referred as to as a STI feature or DTI feature.

FIG. 4A illustrates a top view (or a layout) of a semiconductor device 300 of an array of the circuit cells in the logic region 20 of the IC chip 10, in accordance with some embodiments of the present disclosure. FIG. 4B illustrates a Y-Z cross-sectional view of the semiconductor device 300 along a line A-A′ of FIG. 4A, respectively, in accordance with some embodiments of the present disclosure. FIG. 4C illustrates an X-Z cross-sectional view of the semiconductor device 300 along a line B-B′ of FIG. 4A, respectively, in accordance with some embodiments of the present disclosure. FIG. 4D illustrates an X-Z cross-sectional view of the semiconductor device 300 along a line C-C′ of FIG. 4A, respectively, in accordance with some embodiments of the present disclosure.

The semiconductor device 300 may include circuit cells, for example standard circuit cells (also referred to STD cells). As discussed above, the STD cells may include logic circuits or logic devices, including but not limited to logic circuits such as inverters, NANDs, NORs, flip-flops, or a combination thereof. For the sake of providing an example, the semiconductor device 300 shows an array of circuit cells with a row R1 having circuit cell 302-1, a row R2 having circuit cell 302-2, and a row R3 having circuit cell 302-3. The circuit cell 302-1, the circuit cell 302-2, and the circuit cell 302-3 are also arranged in a column Cl in the Y-direction. The circuit cell 302-1, the circuit cell 302-2, and the circuit cell 302-3 are inverters. It should be understood that the circuit cells 302-1 to 302-3 are merely examples. The present disclosure applies to other types of STD cells as well, for example cells including NORs, ANDs, ORs, flip-flops, or a combination thereof.

The semiconductor device 300 includes active areas 304-1 to 304-6 (may be collectively referred to as active areas 304) that extend lengthwise in the X-direction. More specifically, the circuit cell 302-1 includes active areas 304-1 and 304-2, the circuit cell 302-2 includes active areas 304-3 and 304-4, and the circuit cell 302-3 includes active areas 304-5 and 304-6. Each of active areas 304 includes channel regions, source regions, and drain regions (where source regions and drain regions are collectively referred to as source/drain regions herein) of transistors (e.g., the GAA transistor 200) of the array of the semiconductor device 300.

Referring to FIGS. 4B to 4D, the semiconductor device 300 includes a substrate 310, over which the various features are formed. The substrate 310 may contains a semiconductor material, such as bulk silicon (Si). In some other embodiments, the substrate 310 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). Alternatively, the substrate 310 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates may be fabricated using separation by implantation of oxygen (SIMOX), wafer bonding, and/or other suitable methods.

As shown in FIGS. 4B to 4D, N-type wells NW1 and NW2 and P-type wells PW1 and PW2 are formed in or on the substrate 310. In the present embodiment, the P-type wells PW1 and PW2 are P-type doped regions configured for N-type transistors, and the N-type wells NW1 and NW2 are N-type doped regions configured for P-type transistors. The N-type wells NW1 and NW2 are doped with N-type dopants to have an N-type doping type, such as phosphorus, arsenic, other N-type dopant, or combinations thereof. The P-type wells PW1 and PW2 are doped with P-type dopants have a P-type doping type, such as boron, indium, other P-type dopant, or combinations thereof. Therefore, the N-type wells NW1 and NW2 are also referred to as N-type doping type wells and the P-type wells PW1 and PW2 are also referred to as P-type doping type wells, in accordance with some embodiments. In some implementations, the substrate 310 includes doped regions formed with a combination of P-type dopants and N-type dopants. The various N-type wells and/or P-type wells can be formed directly on and/or in the substrate 310, for example, providing a p-well structure, an n-well structure, a dual-well structure, a raised structure, or combinations thereof. An ion implantation process, a diffusion process, and/or other suitable doping process can be performed to form the various wells.

Furthermore, as shown in FIG. 4B, the active area 304-1 is disposed in the P-type well (or P-Well) PW1, the active areas 304-2 and 304-3 are disposed in the N-type well (or N-Well) NW1, the active areas 304-4 and 304-5 are disposed in the P-type well (or P-Well) PW2, and the active area 304-6 is disposed in the N-type well (or N-Well) NW2. The N-type wells NW1 and NW2 and the P-type wells PW1 and PW2 are arranged alternately in the Y-direction, as shown in FIG. 4B. As shown in FIG. 4B, the active area 304-1 to 304-6 respectively have base fins 310-1 to 310-6 protruded from the substrate 310. In some aspects, the base fins 310-1 to 310-6 are also respectively protruded from the N-type wells NW1 and NW2 and the P-type wells PW1 and PW2.

In some embodiments, the active areas 304-1 to 304-6 are separated from each other in the Y-direction. More specifically, the active areas 304 in different wells are separated by a space S1, the active areas 304 in the same N-type well are separated by a space S2, and the active areas 304 in the same P-type well are separated by a space S3. For example, as shown in FIG. 4A, the active area 304-3 in the N-type well NW1 and the active area 304-4 in the P-type well PW2 are separated by the space S1 in the Y-direction, the active areas 304-2 and 304-3 in the N-type well NW1 are separated by the space S2, and the active areas 304-4 and 304-5 in the P-type well PW2 are separated by the space S3. In some embodiments, the space S1 between the active areas 304-3 and 304-4 is less than the space S2 between the active areas 304-2 and 304-3 and the space S3 between the active areas 304-4 and 304-5. Furthermore, a ratio of the space S2 to the space S1 and a ratio of the space S3 to the space S1 are in a range from 1.1 to 2.

As discussed above, the active area 304-1 to 304-6 respectively have base fins 310-1 to 310-6. As such, the base fins 310-1 to 310-6 in the active areas 304 are also separated from each other by the space S1, the space S2, or the space S3 in the Y-direction. As shown in FIG. 4B, the base fin 310-3 in the N-type well NW1 and the base fin 310-4 in the P-type well PW2 are separated by the space S1 in the Y-direction, the base fins 310-2 and 310-3 in the N-type well NW1 are separated by the space S2, and the base fins 310-4 and 310-5 in the P-type well PW2 are separated by the space S3.

Each of the transistors in the circuit cells 302-1 to 302-3 includes nanostructures 314 similar to the nanostructures 204 discussed above. More specifically, each of the active area 304-1 to 304-6 has the nanostructures 314 in the channel regions of the active areas 304-1 to 304-4. The nanostructures 314 of the active area 304-1 to 304-6 are disposed over the base fins 310-1 to 310-6, as shown in FIG. 4B. As shown in FIGS. 4B to 4D, the nanostructures 314 are suspended over the base fins 310-1 to 310-6 in the N-type wells NW1 and NW2 and the P-type wells PW1 and PW2 of the substrate 310.

In some embodiments, three nanostructures 314 are vertically stacked (or vertically arranged) from each other in the Z-direction for one transistor. However, there may be another appropriate number of nanostructures in one transistor. For example, there may be from 2 to 10 nanostructures 314 in one transistor. The nanostructures 314 further extend lengthwise in the X-direction (FIGS. 4C and 4D) and widthwise in the Y-direction (FIG. 4B). In some embodiments, each of the nanostructures 314 has a thickness T in the Z-direction and in a range from about 3 nm to about 8 nm, as shown in FIG. 4B. As shown in FIG. 4B, in each of the transistors in the circuit cells 302-1 to 302-3, three nanostructures 314 are spaced apart from each other in the Z-direction by a distance D in a range from about 4 nm to about 15 nm. In some embodiments, the nanostructures vertically have a pitch P in the Z-direction and in a range from about 7 nm to about 23 nm.

The nanostructures 314 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 314 include silicon for N-type transistors. In other embodiments, the nanostructures 314 include silicon germanium for P-type transistors. In some embodiments, the nanostructures 314 are all made of silicon, and the type of the transistors depend on the work function metal layer wrapping around the nanostructures 314. In some embodiments, the nanostructures 314 are epitaxially grown using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized.

In the semiconductor device 300, each of the circuit cells 302-1 to 302-3 further includes gate structures, such as gate structures 306-1 to 306-3 (may be collectively referred to as gate structures 306). The gate structures 306-1 to 306-3 extend lengthwise in the Y-direction perpendicular to the X-direction, and are separated from each other in the Y-direction, as shown in FIGS. 4A and 4B. The gate structures 306-1 to 306-3 are also arranged in the Y-direction and aligned in the Y-direction. The gate structures 306-1 to 306-3 are disposed over the channel regions of the respective active areas 304-1 to 304-6 (i.e., the (vertically stacked) nanostructures 314) and disposed between respective source/drain regions of the active areas 304-1 to 304-6 (i.e., P-type source/drain features and/or N-type source/drain features, respectively). In some embodiments, gate structures 306-1 to 306-3 wrap and/or surround suspended, vertically stacked nanostructures 314 in the channel regions of the active areas 304-1 to 304-6, respectively (as shown in FIG. 4B). More specifically, as shown in FIGS. 4A to 4D, each of the gate structures 306-1 to 306-3 wrap around the nanostructures 314 in the channel regions of two of the active areas 304-1 to 304-6. For example, the gate structure 306-2 wraps around the nanostructures 314 in the active area 304-3 in the N-type well NW1 and the nanostructures 314 in the active area 304-4 in the P-type well PW2.

The active areas 304-1 to 304-6 and the gate structures 306-1 to 306-3 are configured to provide each of circuit cells 302-1 to 302-3 with transistors. In the circuit cell 302-1, the gate structure 306-1 engages the active area 304-1 to construct an N-type transistor similar to the N-type transistor N1 of the inverter 100A discussed above, and the gate structure 306-1 engages the active area 304-2 to construct a P-type transistor similar to the P-type transistor P1 of the inverter 100A discussed above.

In the circuit cell 302-2, the gate structure 306-2 engages the active area 304-3 to construct a P-type transistor similar to the P-type transistor P1 of the inverter 100A discussed above, and the gate structure 306-2 engages the active area 304-4 to construct an N-type transistor similar to the N-type transistor N1 of the inverter 100A discussed above.

In the circuit cell 302-3, the gate structure 306-3 engages the active area 304-5 to construct an N-type transistor similar to the N-type transistor N1 of the inverter 100A discussed above, and the gate structure 306-3 engages the active area 304-6 to construct a P-type transistor similar to the P-type transistor P1 of the inverter 100A discussed above.

As shown in FIGS. 4A and 4B, each of the N-type transistors is arranged with one P-type transistor in the Y-direction and share one gate structure with that P-type transistor. For example, in the circuit cell 302-1, the N-type transistor (constructed by the gate structure 306-1 and the active are 304-1) similar to the N-type transistor N1 of the inverter 100A discussed above and the P-type transistor (constructed by the gate structure 306-1 and the active are 304-2) similar to the P-type transistor P1 of the inverter 100A discussed above are arranged in the Y-direction and share the gate structure 306-1. In the circuit cell 302-2, the P-type transistor (constructed by the gate structure 306-2 and the active are 304-3) similar to the P-type transistor P1 of the inverter 100A discussed above and the N-type transistor (constructed by the gate structure 306-2 and the active are 304-4) similar to the N-type transistor N1 of the inverter 100A discussed above are arranged in the Y-direction and share the gate structure 306-2. In the circuit cell 302-3, the N-type transistor (constructed by the gate structure 306-3 and the active are 304-5) similar to the N-type transistor N1 of the inverter 100A discussed above and the P-type transistor (constructed by the gate structure 306-3 and the active are 304-6) similar to the P-type transistor P1 of the inverter 100A discussed above are arranged in the Y-direction and share the gate structure 306-3.

The semiconductor device 300 further includes dielectric gate structures 308 for separating the circuit cells 302-1 to 302-3 from other devices or circuit cells (not shown) in the X-direction. The dielectric gate structures 308 extend lengthwise in the Y-direction. The dielectric gate structures 308 and the circuit cells 302-1 to 302-3 (or the gate structures 306-1 to 306-3) are arranged in the X-direction. More specifically, as shown in FIGS. 4A, 4C, and 4D, in the row R1 of the semiconductor device 300, two dielectric gate structures 308 and the circuit cell 302-1 (or the gate structures 306-1) are arranged in the X-direction. In the row R2 of the semiconductor device 300, two dielectric gate structures 308 and the circuit cell 302-2 (or the gate structures 306-2) are arranged in the X-direction. In the row R3 of the semiconductor device 300, two dielectric gate structures 308 and the circuit cell 302-3 (or the gate structures 306-3) are arranged in the X-direction. In some embodiments, in each of the circuit cells 302-1 to 302-3, two dielectric gate structures 308 are on opposites of the gate structure 306 in the X-direction.

Similar to the isolation feature 216 discussed above, the semiconductor device 300 further includes isolation structures (or isolation feature) 311-1 to 311-7 (may be collectively referred to as isolation structures 311) over the substrate 310 and isolating the adjacent active areas 304. As shown in FIG. 4B, each of the isolation feature 311 includes may include an oxide layer (oxide layers 312-1 to 312-7 for isolation structures 311-1 to 311-7, which may be collectively referred to as oxide layers 312) and a dielectric layer (dielectric layers 313-1 to 313-7 for isolation structures 311-1 to 311-7, which may be collectively referred to as dielectric layers 313) over the oxide layer. The oxide layers 312 may include different structures, such as shallow trench isolation (STI) structures, deep trench isolation (DTI) structures, and/or local oxidation of silicon (LOCOS) structures. In some embodiments, the oxide layers 312 may include or be made of silicon oxide (SiO₂). Therefore, the oxide layers 312 may also be referred to as silicon oxide layers. In some embodiments, each of the isolation structures 311 further includes a liner layer formed before the formation of the oxide layers 312, such that the liner layer is on sidewalls and bottom surfaces of the oxide layers 312. Furthermore, the dielectric layers 313 may have nitrogen, such that the dielectric layers 313 may also be referred to as a nitrogen content dielectric layer 313. In some embodiments, the dielectric layers 313 are silicon nitride layers. In other embodiments, the dielectric layers 313 include or are made of Si3N4, SiON, SiOCN, or combinations thereof.

As shown in FIG. 4B, the isolation structures 311-1 to 311-7 (the oxide layers 312 and dielectric layers 313) are disposed over the N-type wells NW1 and NW2 and the P-type wells PW1 and PW2. More specifically, the isolation structure 311-1 is over the P-type well PW1, the isolation structure 311-2 is over the P-type well PW1 and the N-type well NW1, the isolation structure 311-3 is over the N-type well NW1, the isolation structure 311-4 is over the N-type well NW1 and the P-type well PW2, the isolation structure 311-5 is over the P-type well PW2, the isolation structure 311-6 is over the P-type well PW2 and the N-type well NW2, and the isolation structure 311-7 is over the N-type well NW2, as shown in FIG. 4B.

Furthermore, the isolation structures 311 (the oxide layers 312 and dielectric layers 313) are disposed between the active areas 304 in the Y-direction. More specifically, the isolation structure 311-1 is between an active area for other circuit cell and the active area 310-1 in the P-type well PW1, the isolation structure 311-2 is between the active area 310-1 in the P-type well PW1 and the active area 310-2 in the N-type well NW1, the isolation structure 311-3 is between the active areas 310-2 and 310-3 in the N-type well NW1, the isolation structure 311-4 is between the active area 310-3 in the N-type well NW1 and the active area 310-4 in the P-type well PW2, the isolation structure 311-5 is between the active areas 310-4 and 310-5 in the P-type well PW2, the isolation structure 311-6 is between the active area 310-5 in the P-type well PW2 and the active area 310-6 in the N-type well NW2, and the isolation structure 311-7 is between the active area 310-6 and an active area for other circuit cell in the N-type well NW2, as shown in FIG. 4B.

As discussed above, the active areas 304 are separated from each other by the space S1, the space S2, or the space S3 in the Y-direction. As such, the isolation structures 311-1 to 311-7 also have different length in the Y-direction. The isolation structures 311-2, 311-4, and 312-6 between the active areas 304 in the different wells have the same length as the space S1 discussed above. The isolation structures 311-3 and 311-7 between the active areas 304 in the N-type wells have the same length as the space S2 discussed above. The isolation structures 311-1 and 311-5 between the active areas 304 in the P-type wells have the same length as the space S3 discussed above.

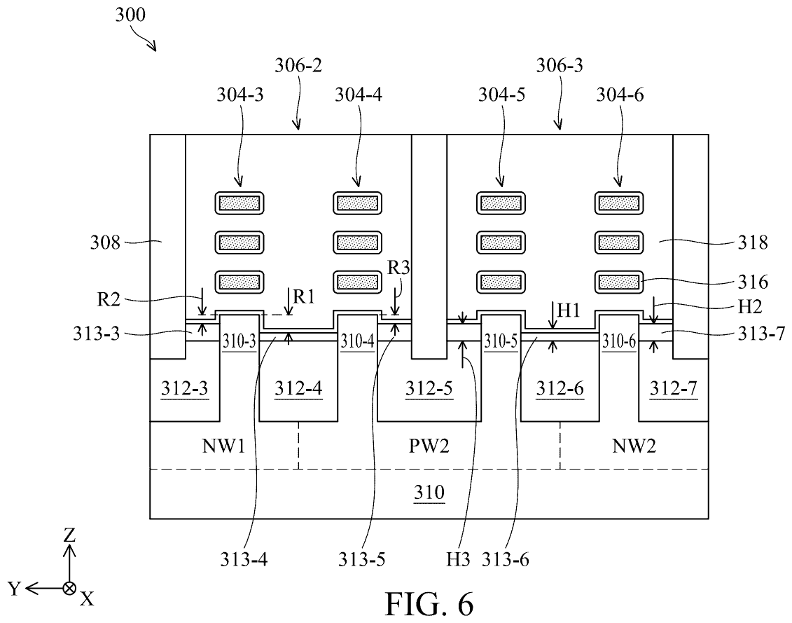

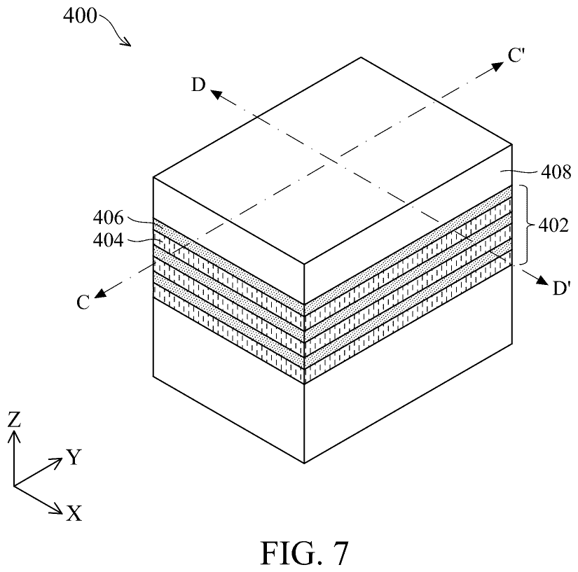

It is noted that the isolation structures 311-1 to 311-7 also have different thicknesses. The thicknesses of the isolation structures 311-2, 312-4, and 312-6 are less than the thicknesses of the isolation structures 311-1, 311-3, 311-5, and 311-7, as shown in FIG. 4B. Furthermore, the oxide layers 312-1 to 312-7 of the isolation structures 311-1 to 311-7 are the same. As such, the dielectric layers 313-1 to 313-7 have different thicknesses. FIG. 6 illustrates a partial enlarged cross-sectional view of the semiconductor device 300 of FIG. 4B, in accordance with some embodiments of the present disclosure. For the sake of simplicity and clarity, FIG. 6 illustrates the partial enlarged cross-sectional view for the circuit cells 302-2 and 302-3.

As shown in FIGS. 4B and 6, the dielectric layer 313-2 over the P-type well PW1 and the N-type well NW1, the dielectric layer 313-4 over the N-type well NW1 and the P-type well PW2, and the dielectric layer 313-6 over the P-type well PW2 and the N-type well NW2 have thicknesses H1. The dielectric layer 313-3 over the N-type well NW1 and the dielectric layer 313-7 over the N-type well NW2 have thicknesses H2. The dielectric layer 313-1 over the P-type well PW1 and the dielectric layer 313-5 over the P-type well PW2 have thicknesses H3. In some embodiments, the thicknesses H1 of the dielectric layers 313-2, 313-4, and 313-6 are less than the thicknesses H2 of the dielectric layers 313-3 and 313-7 and the thicknesses H3 of the dielectric layers 313-1 and 313-5. In some embodiments, the thickness H2 are different than the thickness H3. In other embodiments, the thicknesses H2 and H3 are the same. Furthermore, a ratio of the thickness H2 of the dielectric layers 313-3 and 313-7 to the thickness H1 of the dielectric layers 313-2, 313-4, and 313-6 and a ratio of the thickness H3 of the dielectric layers 313-1 and 313-5 to the thickness H1 of the dielectric layers 313-2, 313-4, and 313-6 are in a range from 1.1 to 1.4, in accordance with some embodiments.

As discussed above, the gate structures 306-1 to 306-3 engage the active areas 304 to construct the transistors. More specifically, the gate structure 306-1 wraps around the nanostructures 314 in the active areas 304-1 and 304-2, the gate structure 306-2 wraps around the nanostructures 314 in the active areas 304-3 and 304-4, and gate structure 306-3 wraps around the nanostructures 314 in the active areas 304-5 and 304-6. Each of the gate structures 306-1 to 306-3 has a gate dielectric layer 316 and a gate electrode layer 318. The gate dielectric layers 316 wrap around each of the nanostructures 314 and the gate electrode layers 318 wrap around the nanostructures 314 and the gate dielectric layer 316. In some embodiments, each of the gate structures 306 further includes an interfacial layer (such as having silicon dioxide, silicon oxynitride, or other suitable materials) between the gate dielectric layer 316 and the nanostructures 314. The gate dielectric layers 316 may include oxide with nitrogen doped dielectric material (initial layer) combined with metal content high-K dielectric material (K value (dielectric constant)>13). For example, gate dielectric layers 316 may include hafnium oxide (HfO₂), which has a dielectric constant in a range from about 18 to about 40. Alternatively, the gate dielectric layers 316 may include other high-K dielectrics, such as TiO₂, HfZrO, Ta₂O₃, HfSiO₄, ZrO₂, ZrSiO₂, LaO, AlO, ZrO, TiO, Ta₂Os, Y₂O₃, SrTiO₃ (STO), BaTiO₃ (BTO), BaZrO, HfLaO, HfSiO, LaSiO, AlSiO, HfTaO, HfTiO, (Ba, Sr) TiO₃ (BST), Al₂O₃, Si₃N₄, oxynitrides (SiON), combinations thereof, or other suitable material. The gate dielectric layers 316 may be formed by chemical oxidation, thermal oxidation, ALD, CVD, and/or other suitable methods.

The gate electrode layer 318 is formed to wrap around the gate dielectric layer 316 and the center portions of the nanostructures 314, as shown in FIGS. 4C and 4D. In some embodiments, the gate electrode layer 318 may include an N-type work function metal layer for N-type transistor or a P-type work function metal layer for P-type transistor. The N-type work function metal layer and the P-type work function metal layer may be selected from a group consisting of TIN, TaN, TiAl, TiAlN, TaAl, TaAlN, TaAlC, TaCN, WNC, Co, Ni, Pt, W, or a combination thereof, in accordance with some embodiments. The material of the N-type work function metal layer and the P-type work function metal layer may be the same. In some embodiments, the material of the N-type work function metal layer and the P-type work function metal layer are different.

In some embodiments, the N-type work function metal layer is a material such as Ti, Al, Ag, Mn, Zr, TiAl, TiAlC, TaC, TaCN, TaSiN, TaAl, TaAlC, TiAlN, other suitable N-type work function materials, or combinations thereof. For example, the N-type work function metal layer may be deposited utilizing ALD, CVD, or the like. However, any suitable materials and processes may be utilized to form the N-type work function metal layer.

In some embodiments, the P-type work function metal layer is a material such as TiN, TaN, Ru, Mo, Al, WN, ZrSi₂, MoSi₂, TaSi₂, NiSi₂, other metal oxides, metal nitrides, metal silicates, transition metal-oxides, transition metal-nitrides, transition metal-silicates, oxynitrides of metals, metal aluminates, zirconium silicate, zirconium aluminate, other suitable P-type work function materials, combinations of these, or the like. Additionally, the P-type work function metal layer may be deposited using a deposition process such as ALD, CVD, or the like, although any suitable deposition process may be used.

In some embodiments, the gate electrode layer 318 may include a single layer or alternatively a multi-layer structure. In some embodiments, the gate electrode layer 318 may further include a capping layer, a barrier layer, and a fill material (not shown). The capping layer may be formed adjacent to the gate dielectric layers 316 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used. The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

As discussed above, the dielectric gate structures 308 extend lengthwise in the Y-direction (e.g., parallel to the gate structures 306) to separate the circuit cells 302-1 to 302-3 from devices or circuit cells (not shown) in the X-direction, as show in FIGS. 4A, 4C, and 4D. Unlike the gate structures 306, however, the dielectric gate structures 308 are not functional gate structures (e.g., do not contain the gate dielectric layer 316 and the gate electrode layer 318). Instead, the dielectric gate structures 308 may be made of electrically insulating materials (e.g., dielectric materials) to provide electrical isolation between various circuit cells. In some embodiments, the dielectric gate structures 308 may be single dielectric layer or multiple layers and selected from a group consisting of SiO₂, SiOC, SION, SiOCN, carbon content oxide, nitrogen content oxide, carbon and nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, or combinations thereof.

As discussed above, the dielectric gate structures 308 and the gate structures 306 are arranged in the X-direction. In the same row (the row R1, R2, or R3) of the semiconductor device 300, a gate pitch is a combination of a gate length of the gate structures 306 in the X-direction and a space between one gate structure 306 to one dielectric gate structure 308 in the X-direction. Furthermore, the gate length of the gate structures 306 in the X-direction and a gate length of the dielectric gate structures 308 in the X-direction are the same. In some embodiments, the gate length of the gate structures 306 is in a range from about 5 nm to about 20 nm.

The semiconductor device 300 further includes dielectric structures 320 are at ends of the gate structures 306 and the dielectric gate structures 308. Therefore, the dielectric structures 320 are also referred to as the gate end dielectric structures. More specifically, the dielectric structures 320 are on opposite sides of the gate structures 306 and the dielectric gate structures 308 in the Y-direction, as shown in FIGS. 4A and 4B. Furthermore, the dielectric structures 320 extend lengthwise in the X-direction to separate the gate structures 306 and/or the dielectric gate structures 308 aligned in the Y-direction. For example, the dielectric structures 320 are between and separate the gate structures 306-1 and 306-2 and between and separate the gate structures 306-2 and 306-3, as shown in FIGS. 4A and 4B. In some embodiments, the dielectric structures 320 also separate the gate structures 306 and/or the dielectric gate structures 308 from gate structures and/or dielectric gate structures of other circuit cells (not shown) in other rows of the semiconductor device 300. Furthermore, the dielectric structures 320 extend vertically into the isolation structures 311. More specifically, as shown in FIG. 4B, the dielectric structures 320 pass through the dielectric layers 313 of the isolation structures 311 and extend vertically into the oxide layers 312 of the isolation structures 311. Therefore, the isolation structures 311 are in contact with sidewalls and bottom surfaces of the dielectric structures 320, as shown in FIG. 4B. The material of the dielectric structures 320 is selected from a group consisting of Si₃N₄, SiON, SiOC, SiOCN, metal content dielectric, high K material (K>=9), or a combination thereof.

The semiconductor device 300 further include gate spacers 322 similar to gate spacers 212 discussed above. More specifically, the gate spacers 322 are on sidewalls of the gate structures 306 and the dielectric gate structures 308, and over the nanostructures 314, as shown in FIGS. 4C and 4D. The gate spacers 322 are over the nanostructures 314 and on top sidewalls of the gate structures 306 and the dielectric gate structures 308, and thus are also referred to as gate top spacers or top spacers. The gate spacers 322 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 322 may include a single layer or a multi-layer structure.

As shown in FIGS. 4C and 4D, the semiconductor device 300 further includes inner spacers 324 on the sidewalls of the gate structures 306 and the dielectric gate structures 308, and below the topmost nanostructures 314. Furthermore, the inner spacers 324 are laterally between the source/drain features 326N (or 326P) and the gate structures 306 and between the source/drain features 326N (or 326P) and the dielectric gate structures 308. The inner spacers 324 are also vertically between adjacent nanostructures 314 and between bottommost nanostructures 314 and the substrate 310. The inner spacers 324 may include a dielectric material having higher K value (dielectric constant) than the gate spacers 322 and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof.

In some embodiments, the gate spacers 322 have a thickness in the X-direction in a range from about 3 nm to about 12 nm, and the inner spacers 324 have a thickness in the X-direction in a range from about 2 nm to about 10 nm. In some embodiments, the thickness of the gate spacers 322 in the X-direction and the thickness of the inner spacers 324 in the X-direction are the same. In other embodiments, the thickness of the gate spacers 322 in the X-direction is less than the thickness of the inner spacers 324 in the X-direction due to the gate spacers 322 are trimmed during sequent processes for forming source/drain contacts.

Referring to FIGS. 4C, 4D, and 4F, the semiconductor device 300 further includes source/drain features 326N and source/drain features 326P over the substrate 310 and in the source/drain regions of the active areas 304. More specifically, the source/drain features 326N and the source/drain features 326P are respectively disposed between one respective gate structure 306 and one respective dielectric gate structure 308. As shown in FIGS. 4C and 4D, the source/drain features 326N are disposed on opposite sides of the respective gate structure 306 in the X-direction to form N-type transistor. Similarly, the source/drain features 326P are disposed on opposite sides of the respective gate structure 306 in the X-direction to form P-type transistor.

Similar to the source/drain features 214 discussed above, the nanostructures 314 extend in the X-direction to connect one source/drain feature 326N/326P to the other source/drain feature 326N/326. More specifically, the source/drain features 326N and the source/drain features 326P are also disposed on opposite sides of the respective nanostructures 314 in the X-direction. Therefore, the source/drain features 326N and the source/drain features 326P are attached and electrically connected to the nanostructures 314 in the X-direction. The source/drain features 326N/326P may also be referred to as source/drain, or source/drain regions. In some embodiments, source/drain feature(s) may refer to a source or a drain, individually or collectively dependent upon the context.

The source/drain features 326N and 326P may be formed by using epitaxial growth. In some embodiments, the source/drain features 326N may include epitaxially-grown material selected from a group consisting of SiP, SiC, SiPC, SiAs, Si, or a combination thereof. In some embodiments, the epitaxially-grown material of the source/drain features 326N may be doped with N-type dopants (such as phosphorus, arsenic, other N-type dopant, or combinations thereof) having a doping concentration in a range from about 2×10¹⁹/cm³ to 3×10²¹/cm³. In some embodiments, the source/drain features 326N for N-type transistors may be respectively referred to as N-type features and N-type source/drain features.

In some embodiments, the source/drain features 326P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 326P may be doped with P-type dopants (such as boron, indium, other P-type dopant, or combinations thereof) having a doping concentration in a range from about 1×10¹⁹/cm³ to 6×10²⁰/cm³. In some embodiments, the source/drain features 326P for P-type transistors may be respectively referred to as P-type source/drain features.

Still referring to FIGS. 4C and 4D, the semiconductor device 300 further includes silicide features 328 over and in contact with the source/drain features 326N and 326P. In some embodiment, each of the silicide features 328 is between the adjacent one gate structure 306 and one dielectric gate structure 308 in the X-direction. The silicide features 328 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. In some embodiments, the silicide features 328 over the source/drain features 326N and the silicide features 328 over the source/drain features 326P have different material. For example, the silicide features 328 over the source/drain features 326N include TiSi and the silicide features 328 over the source/drain features 326P include silicide material selected from a group consist of PtSi, NiSi, CoSi, or MoSi.

Referring to FIGS. 4A to 4D, the semiconductor device 300 further includes source/drain contacts 330-1 to 330-7 for the transistors of the circuit cells 302-1 to 302-3 of the semiconductor device 300 (which may be collectively referred to as source/drain contacts 330), over and in contact with the silicide features 328, and over and electrically connected to the silicide features 328 and the source/drain features 326N and 326P. The source/drain contacts 330 extend lengthwise the Y-direction. As shown in FIG. 6A, in the top view, the source/drain contacts 330 are on opposites of the gate structures 306-1 to 306-3.

In some embodiments, the source/drain contacts 330 are self-aligned source/drain contacts. This means that the source/drain contacts 330 are formed by using the gate spacers 322 as masks. Therefore, the source/drain contacts 330 are in direct contact with the gate spacers 322, as shown in FIGS. 4C and 4D. In some embodiments, the gate spacers 322 are trimmed due to the gate spacers 322 serving as the mask for forming the source/drain contacts 330. Therefore, the thickness of the gate spacers 322 in the X-direction is less than the thickness of the inner spacers 324 in the X-direction, as discussed above. In some embodiments, top surfaces of the source/drain contacts 330 are substantially level with top surfaces of the gate structures 306 and gate spacers 322 when the source/drain contacts 330 are self-aligned source/drain contacts.

In some embodiments, the source/drain contacts 330 are non-self-aligned source/drain contacts. This means that the source/drain contacts 330 are not formed by using the gate spacers 322 as masks. In these embodiments, the source/drain contacts 330 may be separated from the gate spacers 322 by a dielectric layer (e.g., an inter-layer dielectric (ILD) layer 334). As such, the contact-to-gate parasitic capacitance is reduced. Furthermore, in these embodiments, the thickness of the gate spacers 322 in the X-direction and the thickness of the inner spacers 324 in the X-direction are the same. In other embodiments, the thickness of the gate spacers 322 in the X-direction is greater than the thickness of the inner spacers 324 in the X-direction. In some embodiments, the top surfaces of the source/drain contacts 330 are higher than the top surfaces of the of the gate structures 306 and gate spacers 322 when the source/drain contacts 330 are non-self-aligned source/drain contacts.

The source/drain contacts 330-2, 330-4, and 330-6 each is directly disposed over and electrically connected to one source/drain feature 326N and one source/drain feature 326P in the same circuit cell. The source/drain contacts 330-1, 330-3, 330-5, 330-7 each is disposed over and electrically connected to two source/drain features 326N or 326P in two circuit cells in adjacent two rows of the semiconductor device 300. More specifically, as shown in FIG. 6A, the source/drain contact 330-1 is over and electrically connected to one source/drain feature 326N of the transistor constructed by the active area 304-1 and the gate structure 306-1; the source/drain contact 330-2 is over and electrically connected to the other source/drain feature 326N of the transistor constructed by the active area 304-1 and the gate structure 306-1 and one source/drain feature 326P of the transistor constructed by the active area 304-2 and the gate structure 306-1; the source/drain contact 330-3 is over and electrically connected to the other source/drain feature 326P of the transistor constructed by the active area 304-2 and the gate structure 306-1 and one source/drain feature 326P of the transistor constructed by the active area 304-3 and the gate structure 306-2; the source/drain contact 330-4 is over and electrically connected to the other source/drain feature 326P of the transistor constructed by the active area 304-3 and the gate structure 306-2 and one source/drain feature 326N of the transistor constructed by the active area 304-4 and the gate structure 306-2; the source/drain contact 330-5 is over and electrically connected to the other source/drain feature 326N of the transistor constructed by the active area 304-4 and the gate structure 306-2 and one source/drain feature 326N of the transistor constructed by the active area 304-5 and the gate structure 306-3; the source/drain contact 330-6 is over and electrically connected to the other source/drain feature 326N of the transistor constructed by the active area 304-5 and the gate structure 306-3 and one source/drain feature 326P of the transistor constructed by the active area 304-6 and the gate structure 306-3; and the source/drain contact 330-7 is over and electrically connected to the other source/drain feature 326P of the transistor constructed by the active area 304-6 and the gate structure 306-3.

Furthermore, the source/drain contacts 330-1, 330-3, 330-5, and 330-7 each is also disposed over and the dielectric structures 320. More specifically, as shown in FIG. 4A, the source/drain contacts 330-1, 330-3, 330-5, and 330-7 are extend in the Y-direction to overlap the dielectric structures 320. In some embodiments, the source/drain contacts 330-1, 330-3, 330-5, and 330-7 are in contact with the dielectric structures 320.

The source/drain contacts 330 may each include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 330 may each include single conductive material layer or multiple conductive layers.

Referring to FIGS. 4A to 4D, the semiconductor device 300 further includes a cap layer 333, an inter-layer dielectric (ILD) layer 334, and an inter-metal dielectric (IMD) layer 336. The cap layer 333 is over the gate structures 306 for protecting the gate structures 306. In some embodiments, the cap layer 333 includes silicon nitride (Si₃N₄). The ILD layer 334 is over the substrate 310, the isolation structures 311, the gate structures 306, the dielectric gate structure 308, the source/drain contacts 330, and the cap layer 333. The IMD layer 336 is over the ILD layer 334, the gate structures 306, the dielectric gate structure 308, the source/drain contacts 330, and the cap layer 333.

The ILD layer 334 and the IMD layer 336 include a dielectric material including, for example, silicon oxide, silicon nitride, silicon oxynitride, TEOS-formed oxide, PSG, BPSG, low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, other low-k dielectric material, or combinations thereof. In some embodiments, the ILD layer 334 and the IMD layer 336 are a dielectric layer that includes a low-k dielectric material (generally referred to as a low-k dielectric layer). The ILD layer 334 and the IMD layer 336 may include a multilayer structure having multiple dielectric materials.

Referring to FIGS. 4A to 4D, the semiconductor device 300 further includes gate vias VG, vias VD, and metal layers M1. The gate vias VG and vias VD are disposed in the ILD layer 334 and the metal layers M1 are disposed in the IMD layer 336. The metal layers M1 are over and electrically connected to respective gate structures 306 and respective source/drain contacts 330. The gate vias VG are over and in contact with the gate structures 306 and electrically connect the gate structures 306 to respective metal layers M1. The vias VD are over and in contact with the source/drain contacts 330 and electrically connect the source/drain contacts 330 to respective metal layers M1. The materials of the gate vias VG, the vias VD, and the metal layers M1 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

As shown in FIG. 4A to 4D, the metal layers M1 extend in the X-direction and further include metal layers MN, VM1, VM2, VM3, and VM4. The metal layers MN are disposed within the cell boundaries (e.g., the circuit cells 302-1 to 302-3) in the top view, as shown in FIG. 4A. The metal layers VM1, VM2, VM3, and VM4 are disposed overlap the dielectric structures 320 in the top view, as shown in FIG. 4A. In some embodiments, a width of the metal layers VM1, VM2, VM3, and VM4 in the Y-direction is greater than a width of the metal layers MN in the Y-direction.

The metal layers M1 are respectively connected to respective gate structures 306 and respective source/drain contacts 330 through respective gate vias VG and VD. In some embodiments, the gate vias VG, VD and metal layers M1 are used to construct connections of the transistors in the circuit cells 302-1 to 302-3. In some embodiments, the vias VD and metal layers M1 are connected to power sources or voltage sources (not shown) to provide voltage (VDD or VSS) to the transistors in the circuit cells 302-1 to 302-3. In the present embodiment, the metal layers VM1 and VM3 are connected to a VSS power source (not shown) and the metal layers VM2 and VM4 are connected to a VDD power source (not shown). Therefore, the metal layers VM2 and VM4 may be also referred to as the (VDD) power metal line, the (VDD) power line, or (VDD) power conductor, and the metal layers VM1 and VM3 may be also referred to as the (VSS) power metal line, the (VSS) power line, or (VSS) power conductor.

As shown in FIG. 4A, the vias VD which electrically connected to the metal layers VM2 and VM3 have a larger via size than other vias VD and gate vias VG, in accordance with some embodiments. Therefore, due to small resistances of larger size vias VD, the transistors in the circuit cells 302-1 to 302-3 may be provided with voltage (or power) with low voltage drop, thereby improving the performance of the semiconductor device 300.

As discussed above, the base fins 310-1 to 310-6 in the active areas 304 are separated from each other by the space S1, the space S2, or the space S3 in the Y-direction. More specifically, the active areas 304 in different wells are separated by a space S1, the active areas 304 in the same N-type well are separated by a space S2, and the active areas 304 in the same P-type well are separated by a space S3. Therefore, the active areas 304 in the same circuit cell 302 are separated from each other by the space S1 in the Y-direction, and the active areas 304 in different circuit cells 302 are separated from each other by the space S2 or the space S3 in the Y-direction, as shown in FIGS. 4B and 6. The space S1 is less than the space S2 and the space S3, as discussed above.

As such, the gate structures 306 has a smaller width in the Y-direction. More specifically, portions of the gate structures 306 between the active areas 304 in different wells has a smaller width in the Y-direction (equal to the space S1). Such smaller width of the gate structures 306 in the Y-direction reduces the gate-to-contact parasitic capacitance. Furthermore, the larger spaces S2 and S3 ensure that there is enough space between the gate structures 306 in the Y-direction, such that the dielectric structures 320 have a larger process window that can be formed between the gate structures 306 in the Y-direction. In addition, the larger space between the gate structures 306 in the Y-direction reduces the gate-to-gate parasitic capacitance.

As discussed above, the ratio of the space S2 to the space S1 and the ratio of the space S3 to the space S1 are in a range from 1.1 to 2. If the ratio of the space S2 or the space S3 to the space S1 is too small (the ratio is less than 1.1), then the space S2 or the space S3 is too small and/or the space S1 is too large, thereby the process window for the dielectric structures 320 is impacted and/or the gate-to-contact parasitic capacitance cannot be significantly reduced. If the ratio of the space S2 or the space S3 to the space S1 is too large (the ratio is greater than 2), the space S2 or the space S3 is too large and/or the space S1 is too small, thereby the size of the circuit cells 302 is increased to impact the device density and/or the process window for the gate structures 306 is impacted.

As shown in FIG. 4B, the isolation structures 311 (the oxide layers 312 and dielectric layers 313) have different thicknesses, as discussed above. More specifically, as discussed above, the dielectric layers 313 under and in contact with the gate structures 306 have different thicknesses H1, H2, and H3. Therefore, portions of the gate structures 306 over the different well also have different thicknesses. For the sake of simplicity and clarity, take the gate structure 306-2 shown in FIG. 6 for an example: a portion of the gate structure 306-2 over the N-type well NW1 and the P-type well PW2, lower top surfaces of the base fins 310-3 and 310-4 (or all top surfaces of the base fins 310-1 to 310-6), and between the active area 304-3 and 304-4 has a thickness R1; a portion of the gate structure 306-2 over the N-type well NW1, lower top surfaces of the base fins 310-2 and 310-3 (or all top surfaces of the base fins 310-1 to 310-6), and between the active area 304-2 and 304-3 has a thickness R2; and a portion of the gate structure 306-2 over the P-type well PW2, lower top surfaces of the base fins 310-4 and 310-5 (or all top surfaces of the base fins 310-1 to 310-6), and between the active area 304-2 and 304-3 has a thickness R3. In some embodiments, the thickness R1 is greater than the thickness R2 and thickness R3, as shown in FIG. 6. Furthermore, a ratio of the thickness R1 to the thickness R2 and a ratio of the thickness R1 to the thickness R3 are in a range from 1.1 to 3.

In some embodiments, a distance from the bottom surfaces of the gate structures 306 over the isolation structures 311-2, 311-4, and 311-6 to the top surfaces of the base fins 310-1 to 310-6 (equal to the thickness R1) is greater than a distance from the bottom surfaces of the gate structures 306 over the isolation structures 311-3 and 311-7 to the top surfaces of the base fins 310-1 to 310-6 (equal to the thickness R2) and a distance from the bottom surfaces of the gate structures 306 over the isolation structures 311-1 and 311-5 to the top surfaces of the base fins 310-1 to 310-6 (equal to the thickness R3). Furthermore, in some aspects, bottom surfaces of the gate structures 306 in contact with the dielectric layers 313-2, 313-4, and 313-6 are lower than bottom surfaces of the gate structures 306 in contact with the dielectric layers 313-3 and 313-7 and bottom surfaces the gate structures 306 in contact with the dielectric layers 313-1 and 313-5.

In some embodiments, a ratio of a distance from the bottom surfaces of the gate structures 306 in contact with the dielectric layers 313-2, 313-4, and 313-6 (or over the isolation structures 311-2, 311-4, and 311-6) to the top surfaces of the base fins 310-1 to 310-6 (equal to the thickness R1) to a distance from the bottom surfaces of the gate structures 306 in contact with the dielectric layers 313-3 and 313-7 (or over the isolation structures 311-3 and 311-7) to the top surfaces of the base fins 310-1 to 310-6 (equal to the thickness R2) or to a distance from the bottom surfaces of the gate structures 306 in contact with the dielectric layers 313-1 and 313-5 (or over the isolation structures 311-1 and 311-5) to the top surfaces of the base fins 310-1 to 310-6 (equal to the thickness R3) is in a range from 1.1 to 3.

The larger thickness R1 is due to the smaller thickness H1 of the dielectric layers 313-2, 313-4, and 313-6, which ensure that there is enough process window in release process (for removing SiGe layers). In addition, the larger space between the gate structures 306 in the Y-direction reduces the gate-to-gate parasitic capacitance. The smaller thicknesses R2 and R3 is due to the larger thicknesses H2 and H3 of the dielectric layers 313-1, 313-3, 313-5, and 313-7, which reduces the contact area between the gate structures 306 and the base fins 310-1 to 310-6, thereby reducing the leakage current through the base fins 310-1 to 310-6.

As discussed above, the ratio of the thickness H2 to the thickness H1 and the ratio of the thickness H3 to the thickness H1 are in a range from 1.1 to 1.4. If the ratio of thickness H2 or the thickness H3 to thickness H1 is too small (the ratio is less than 1.1, and thus the ratio of the thickness R1 to the thickness R2 or the thickness R3 is less than 1.1), thickness H2 or the thickness H3 is too small and/or the thickness H1 is too large, thereby the leakage current cannot be significantly reduced and/or process window in release process is impacted. If the ratio of thickness H2 or the thickness H3 to thickness H1 is too large (the ratio is greater than 4, and thus the ratio of the thickness R1 to the thickness R2 or the thickness R3 is greater than 3), thickness H2 or the thickness H3 is too large and/or the thickness H1 is too small, thereby the performance of the transistor is impacted.

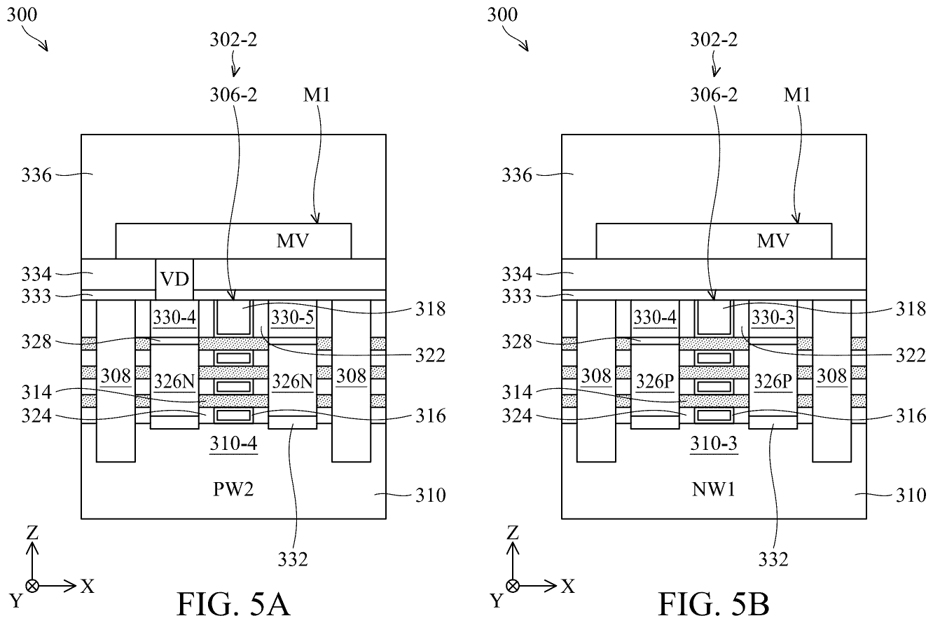

FIG. 5A illustrates an X-Z cross-sectional view of the semiconductor device 300 along a line B-B′ of FIG. 4A, respectively, in accordance with some alternative embodiments of the present disclosure. FIG. 5B illustrates an X-Z cross-sectional view of the semiconductor device 300 along a line C-C′ of FIG. 4A, respectively, in accordance with some alternative embodiments of the present disclosure. The semiconductor device 300 shown in FIGS. 5A and 5B is similar to the semiconductor device 300 shown in FIGS. 4C and 4D discussed above, except that the semiconductor device 300 shown in FIGS. 5A and 5B further includes bottom dielectric layers 332 under the source/drain features 326N and 326P and over the substrate 310.

In some embodiment, the bottom dielectric layers 332 are in contact with the sidewalls of the inner spacers 324, in the X-Z cross-sectional view, as shown in FIGS. 5A and 5B. In some aspect, the bottom dielectric layers 332 are in contact with and between the inner spacers 324, in the X-Z cross-sectional view. In some embodiments, the dielectric material of the bottom dielectric layer 332 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), other suitable material(s), or combinations thereof, and may be deposited by CVD, PVD, ALD, HDPCVD, MOCVD, RPCVD, PECVD, LPCVD, ALCVD, APCVD, other suitable methods, or combinations thereof. It should be noted that the source/drain features 326N and 326P are separated from the substrate 310 by the bottom dielectric layers 332. As such, it prevents the leakage current of the resultant transistors from one source/drain feature 326N/326P to another source/drain feature 326N/326P through the substrate 310, thereby improving performances of the resultant transistors.

In some embodiments, the bottom dielectric layers 332 the bottom dielectric layers 332 are disposed under the source/drain features 326N and the source/drain features 326P are still over and in contact with the substrate 310 without the bottom dielectric layers 332 (as shown in FIG. 4D). Therefore, each of the source/drain features 326P has a larger volume than the source/drain features 326N to keep strain for nanostructures 314 in the P-type transistor, thereby improving the performance of the P-type transistor in the semiconductor device 300.

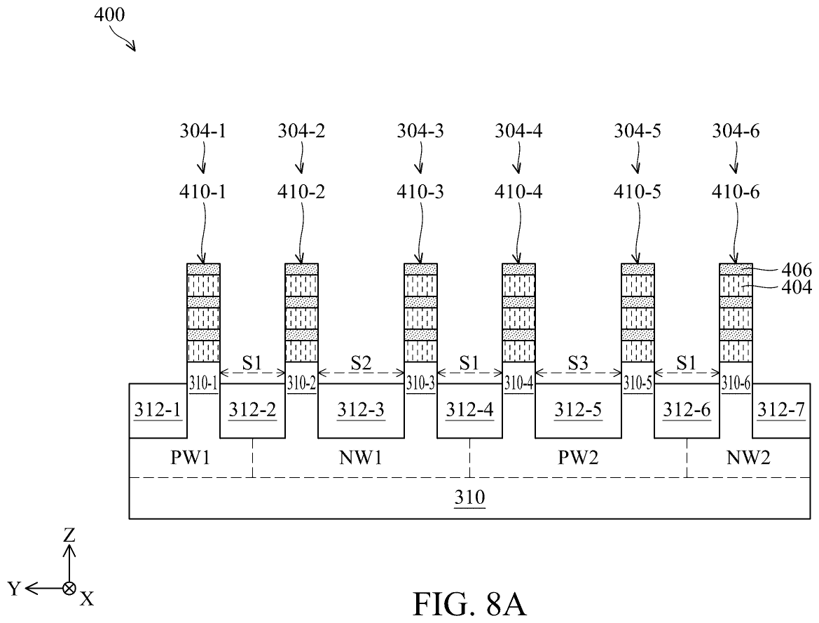

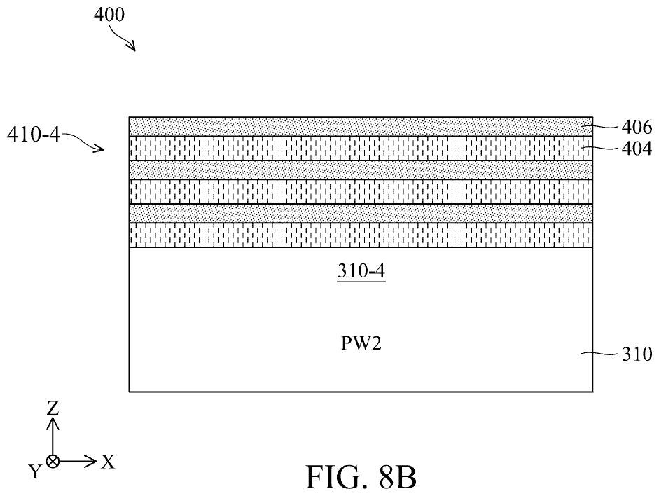

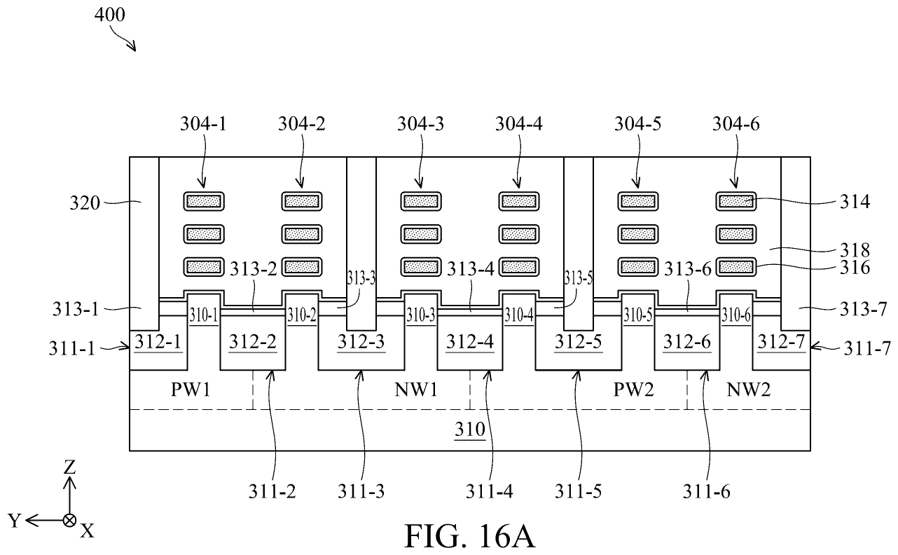

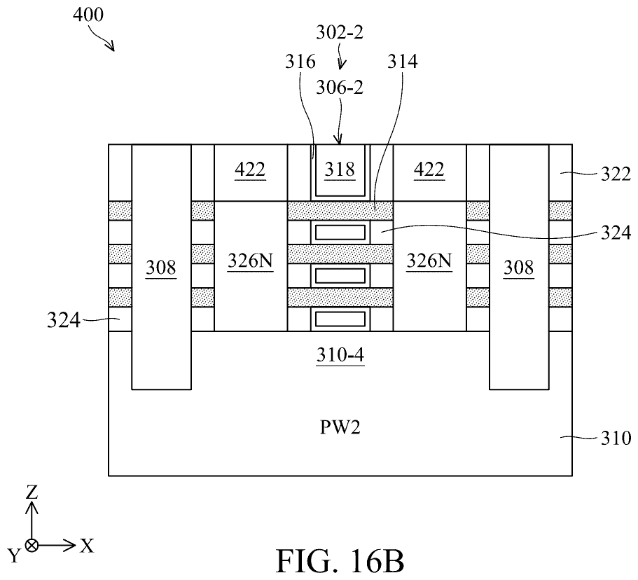

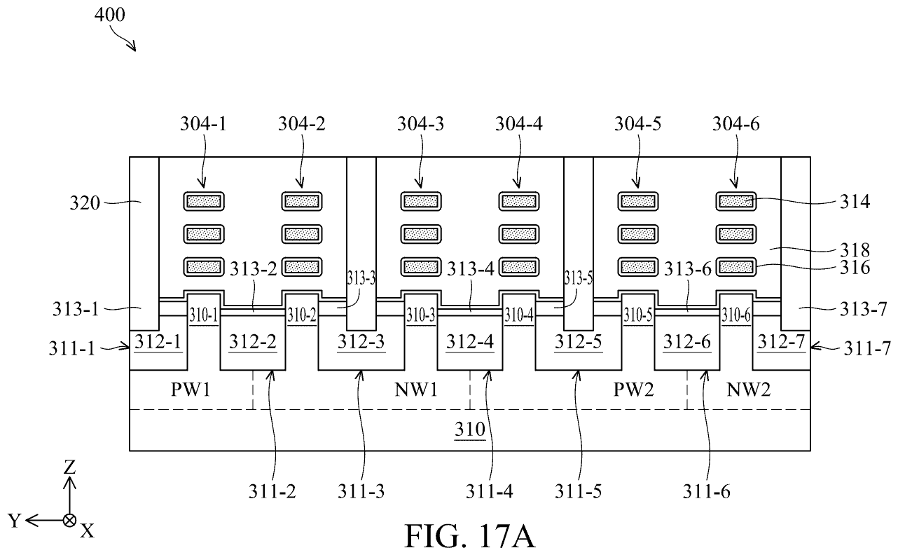

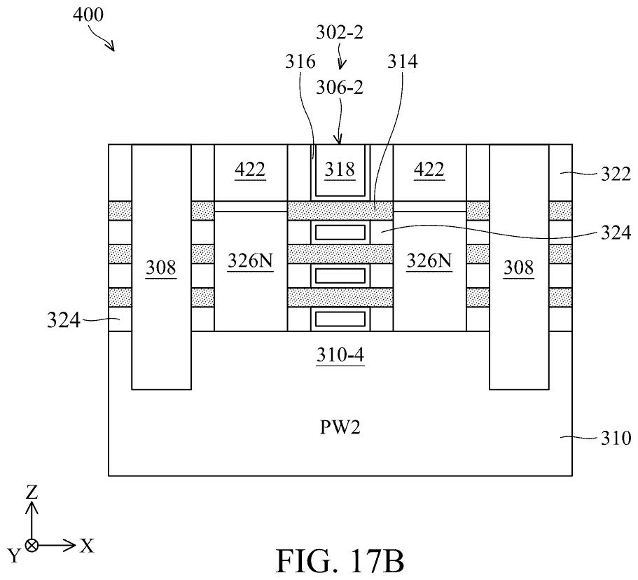

FIG. 7 illustrates a perspective view of a workpiece 400 at a fabrication stage for the semiconductor device 300, in accordance with some embodiments of the present disclosure. FIGS. 8A, 9A, 10A, 11A, 12A, 13A, 14A, 15A, 16A, and 17A illustrate Y-Z cross-sectional views of the workpiece 400 at various fabrication stage along a line C-C′ of FIG. 7, respectively, in accordance with some embodiments of the present disclosure. FIGS. 8B, 9B, 10B, 11B, 12B, 13B, 14B, 15B, 16B, and 17B illustrate X-Z cross-sectional views of the workpiece 400 at various fabrication stage along a line D-D′ of FIG. 7, respectively, in accordance with some embodiments of the present disclosure.

Referring to FIG. 7, a stack 402 is formed over the substrate 310. In some embodiments, the substrate 310 may include one or more well regions, such as n-type well regions (e.g., the n-type wells NW1 and NW2 discussed above) doped with an n-type dopant (i.e., phosphorus (P) or arsenic (As)) or p-type well regions (e.g., the p-type wells PW1 and PW2 discussed above) doped with a p-type dopant (i.e., boron (B)), for forming different types of devices. The doping the n-type wells and the p-type wells may be formed using ion implantation or thermal diffusion.

The stack 402 includes semiconductor layers 404 and 406, and the semiconductor layers 404 and 406 are alternatingly stacked in the Z-direction. The semiconductor layers 404 and the semiconductor layers 406 may have different semiconductor compositions. In some embodiments, semiconductor layers 404 are formed of silicon germanium (SiGe) and the semiconductor layers 406 are formed of silicon (Si). In these embodiments, the additional germanium content in the semiconductor layers 404 allow selective removal or recess of the semiconductor layers 404 without substantial damage to the semiconductor layers 406, so that the semiconductor layers 404 are also referred to as sacrificial layers. In some embodiments, the semiconductor layers 404 and 406 are epitaxially grown over (on) the substrate 310 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layers 404 and the semiconductor layers 406 are deposited alternatingly, one-after-another, to form the stack 402.

It should be noted that three (3) layers of the semiconductor layers 404 and three (3) layers of the semiconductor layers 406 are alternately and vertically arranged (or stacked) as shown in FIG. 8A, which are for illustrative purposes only and not intended to be limiting beyond what is specifically recited in the claims. The number of layers depends on the desired number of channels members for the semiconductor device. In some embodiments, there may be from 2 to 10 semiconductor layers 404 alternating with 2 to 10 semiconductor layers 406 in the stack 402.

For patterning purposes, the workpiece 400 may also include a hard mask layer 408 over the stack 402. The hard mask layer 408 may be a single layer or a multi-layer. In some embodiments, the hard mask layer 408 is a single layer and includes a silicon germanium layer. In some embodiments, the hard mask layer 408 is a multi-layer and includes a silicon nitride layer and a silicon oxide layer over the silicon nitride layer. In some other embodiments, the hard mask layer 408 is a multi-layer and includes a silicon germanium layer and a silicon layer over the silicon germanium layer.

Referring to FIGS. 8A and 8B, after the formation of the stack 402, the active areas 304-1 to 304-6 are defined on the workpiece 400 for patterning the stack 402 to form fins 410-1 to 410-6 (which may be collectively referred to as fins 410) over the substrate 310. In some embodiments, after the formation of the fins 410, the hard mask layer 408 is removed. Each of the fins 410-1 to 410-6 includes a stack portion semiconductor layers 404 and 406 alternating stacked in the Z-direction and the base fin discussed above (i.e., the base fins 310-1 to 310-6) over the stack portion, as shown in FIG. 8A. Furthermore, the spaces S1, S2, and S3 discussed above between the active areas 304-1 to 304-6 are also defined after the formation of the fins 410.

Still referring to FIGS. 8A and 8B, after the definition of the active areas 304 and the formation of the fins 410, the oxide layers 312 (including the oxide layers 312-1 to 312-7, as discussed above) of the isolation structures 311 discussed above are formed over the substrate 310. The oxide layers 312 are also formed between the active areas 304. In some embodiments, a dielectric material for the oxide layers 312 is first deposited over the substrate 310. Specifically, the dielectric material is deposited and formed over the fins 410 and the substrate 310 to cover the fins 410 and the substrate 310. In some aspects, the dielectric material is formed to wrap around the fins 410. The deposited dielectric material is then thinned and planarized, for example by a chemical mechanical polishing (CMP) process. The planarized dielectric material is further recessed by a dry etching process, a wet etching process, and/or a combination thereof to form the oxide layers 312. In some embodiments, before the formation of the oxide layers 312, liner layers may be conformally deposited over the substrate 310 using ALD or CVD.

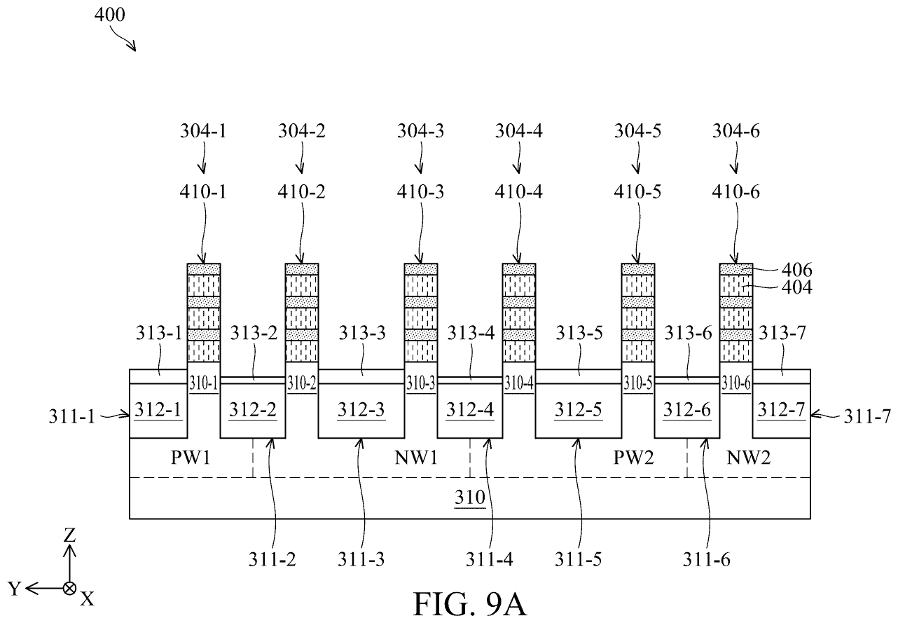

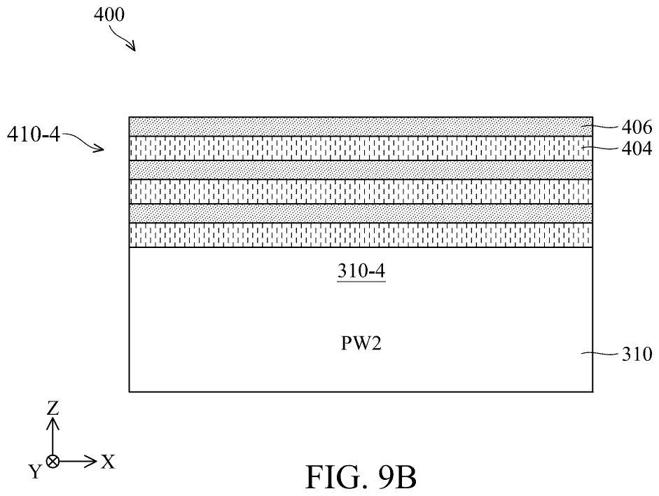

Referring to FIGS. 9A and 9B, after the oxide layers 312 of the isolation structures 311 discussed above are formed, the dielectric layers 313 (including the dielectric layers 313-1 to 313-7, as discussed above) of the isolation structures 311 discussed above are formed over the oxide layers 312. The dielectric layers 313 are also formed between the active areas 304. As discussed above, the dielectric layers 313 have different thickness H1, H2, and H3. In some embodiments, one or more lithography and depositing processes are performed to achieve the different thickness H1, H2, and H3 for the dielectric layers 313. In other embodiments, due to the different spaces S1, S2, and S3 between the active areas 304-1 to 304-6 discussed above, a selective grow process can be performed to achieve the different thickness H1, H2, and H3 for the dielectric layers 313. More specifically, the formation of dielectric layers 313 to be formed in the larger spaces S2 and S3 is controlled to be formed at a higher formation rate and the formation of dielectric layers 313 to be formed in the smaller spaces S1 is controlled to be formed at a lower formation rate. Therefore, the dielectric layers 313 with the different thickness H1, H2, and H3 are achieved.

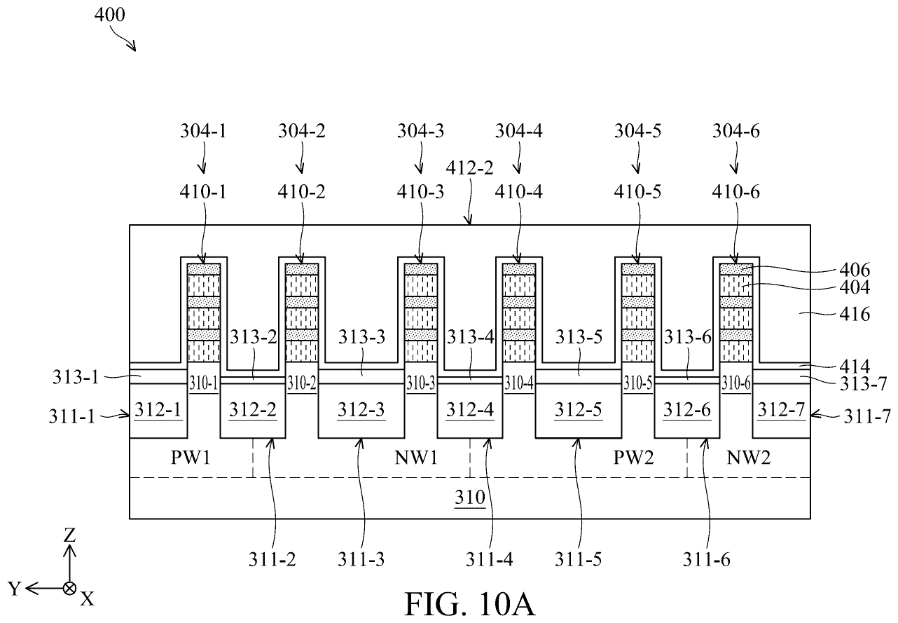

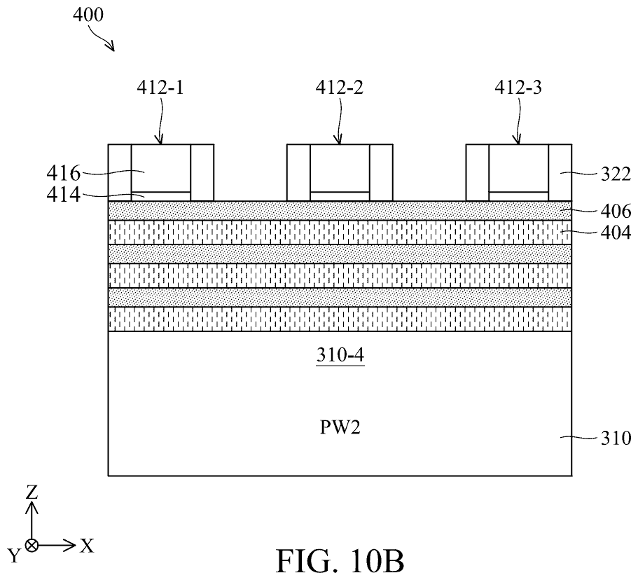

Referring to FIGS. 10A and 10B, dummy gate structures 412-1 to 412-3 (may be collectively referred to as the dummy gate structures 412) are formed over the fins 410. The dummy gate structures 412 extend in the Y-direction, as shown in FIG. 10A. In some embodiments, to form the dummy gate structures 412, a dummy interfacial material for dummy interfacial layers 414 is first formed over fins 410. In some embodiments, the dummy interfacial layer 414 may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material for dummy gate electrodes 416 is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or a combination thereof. The dummy gate material and/or the dummy interfacial material may be formed by way of a thermal oxidation process and/or a deposition process (e.g., physical vapor deposition (PVD), CVD, PECVD, and ALD).

After the formation of the dummy interfacial material and the dummy gate material, one or more etching processes may be performed to pattern the dummy gate material for the dummy gate electrodes 416 and the dummy interfacial material for the dummy interfacial layers 414, thereby forming the dummy gate structures 412 each having the dummy interfacial layer 414 and the dummy gate electrode 416. The dummy interfacial layers 414 may also be referred to as dummy gate dielectrics. The dummy gate structures 412 may undergo a gate replacement process through subsequent processing to form metal gates, such as a high-k metal gate, as discussed in greater detail below.

Still referring to FIGS. 10A and 10B, after the formation of the dummy gate structures 412, the gate spacers 322 discussed above are formed on sidewalls of the dummy gate structures 412 and over the top surfaces of the fins 410. More specifically, the gate spacers 322 are formed on opposite sidewalls of the dummy gate structures 412. In some embodiments, the gate spacers 322 may be formed by conformally depositing a spacer layer (containing the dielectric material) over the fins 410 and dummy gate structures 412, followed by an anisotropic etching process to remove top portions of the spacer layer from the top surfaces of the fins 410 and dummy gate structures 412. After the etching process, portions of the spacer layer on the sidewall surfaces of the fins 410 and the dummy gate structures 412 substantially remain and become the gate spacers 322. In some embodiments, the anisotropic etching process is a dry (e.g., plasma) etching process. Additionally or alternatively, the formation of the gate spacers 322 may also involve chemical oxidation, thermal oxidation, ALD, CVD, and/or other suitable methods. The gate spacers 322 may also be interchangeably referred to as top spacers.

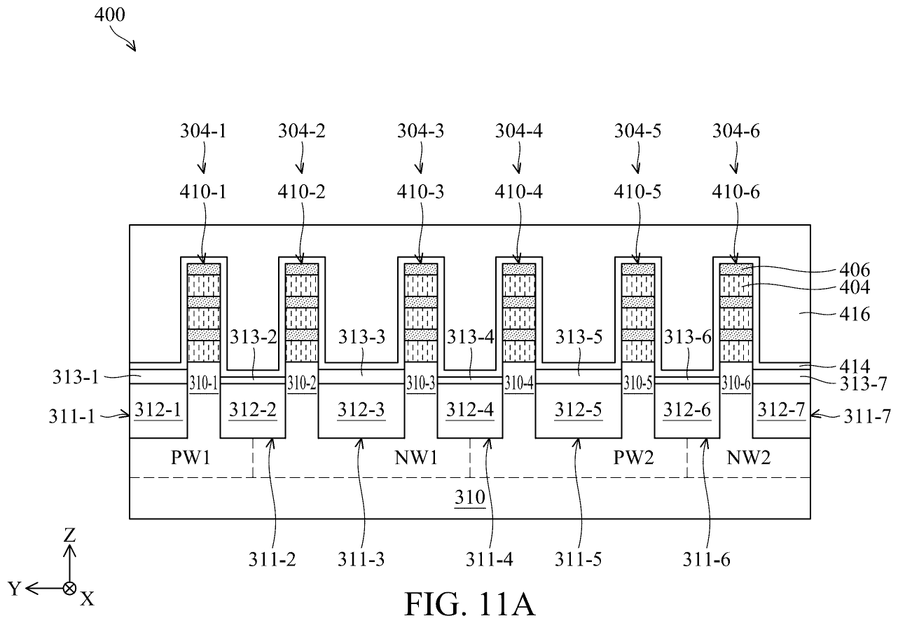

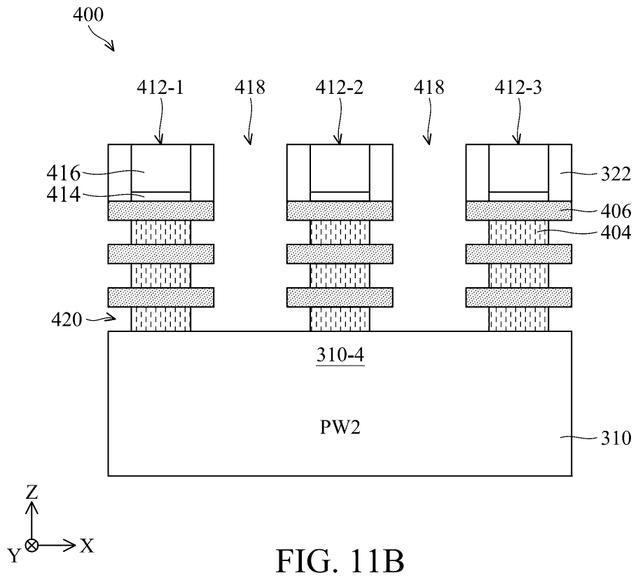

Referring to FIGS. 11A and 11B, the fins 410 are recessed to form source/drain trenches 418 in the fins 410 (or passing through the semiconductor layers 404 and 406). More specifically, the source/drain trenches 418 are formed on opposite sides of the dummy gate structures 412 and in the fins 410. The source/drain trenches 418 may be formed by performing one or more etching processes to remove portions of the semiconductor layers 404, the semiconductor layers 406 that do not vertically overlap or be covered by the dummy gate structures 412 and the gate spacers 322. In some embodiments, a single etchant may be used to remove the semiconductor layers 404 and the semiconductor layers 406, whereas in other embodiments, multiple etchants may be used to perform the etching process.

Still referring to FIGS. 11A and 11B, after the formation of the source/drain trenches 418, side portions of the semiconductor layers 404 are removed via a selective etching process. Specifically, the selective etching process is performed that selectively etches the side portions of the semiconductor layers 404 below the gate spacers 322 through the source/drain trenches 418, with minimal (or no) etching of semiconductor layers 406, such that gaps 420 are formed between the semiconductor layers 406 as well as between the semiconductor layers 406 and the substrate 310, below the gate spacers 322. The etching process is configured to laterally etch (e.g., along the X-direction) the semiconductor layers 404 below the gate spacers 322. The selective etching process is a dry etching process, a wet etching process, other suitable etching process, or a combination thereof.

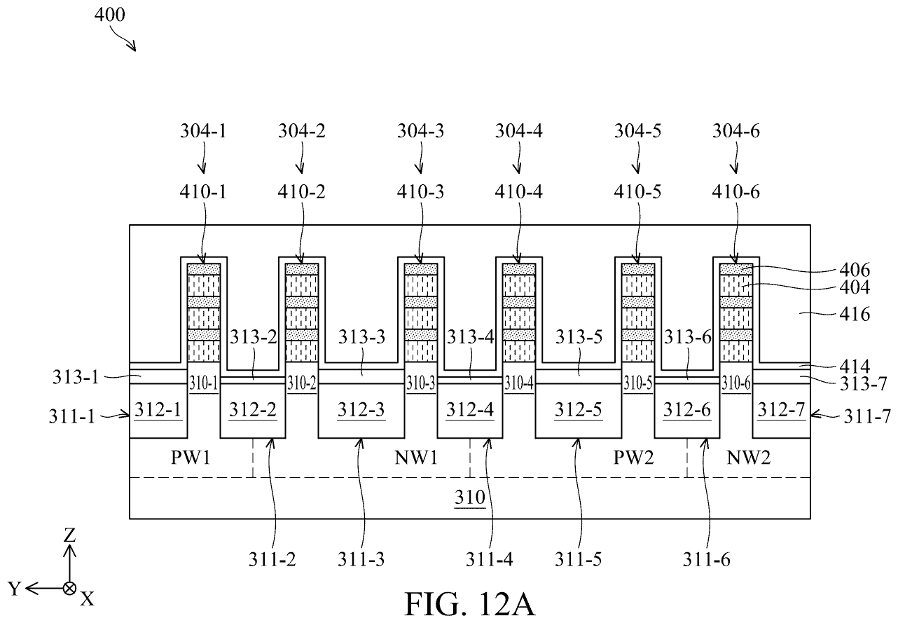

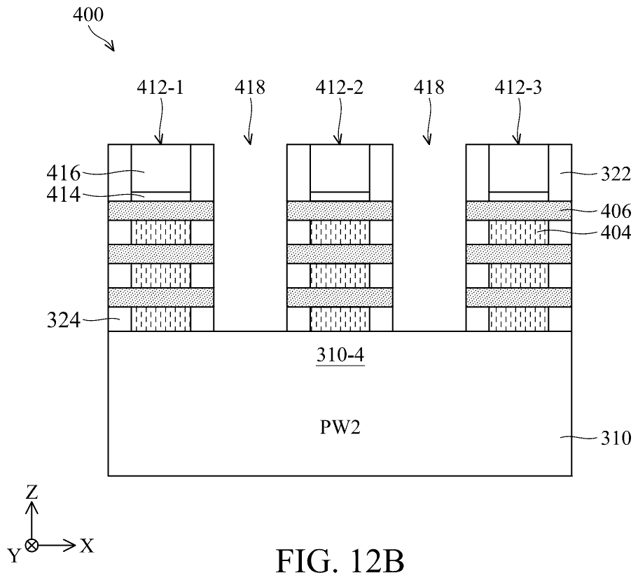

Referring to FIGS. 12A and 12B, the inner spacers 324 discussed above are formed to fill the gaps 420. The inner spacers 324 are under the gate spacers 322 and between the semiconductor layers 406 as well as between the semiconductor layers 406 and the substrate 310. In some embodiments, sidewalls of the inner spacers 324 are aligned to sidewalls of the gate spacers 322 and the semiconductor layers 406, as shown in FIG. 12B. In order to form the inner spacers 324, a deposition process forms a spacer layer into the source/drain trenches 418 and the gaps 420, such as CVD, PVD, ALD, HDPCVD, MOCVD, RPCVD, PECVD, LPCVD, ALCVD, APCVD, other suitable methods, or a combination thereof. The spacer layer partially (and, in some embodiments, completely) fills the source/drain trenches 418. The deposition process is configured to ensure that the spacer layer fills the gaps 420 between the semiconductor layers 406 as well as between the semiconductor layer 406 and the substrate 310 under the gate spacers 322. An etching process is then performed that selectively etches the spacer layer to form inner spacers 324 (as shown in FIG. 12B) with minimal (to no) etching of the semiconductor layer 406, the substrate 310, the dummy gate structures 412, and the gate spacers 322.

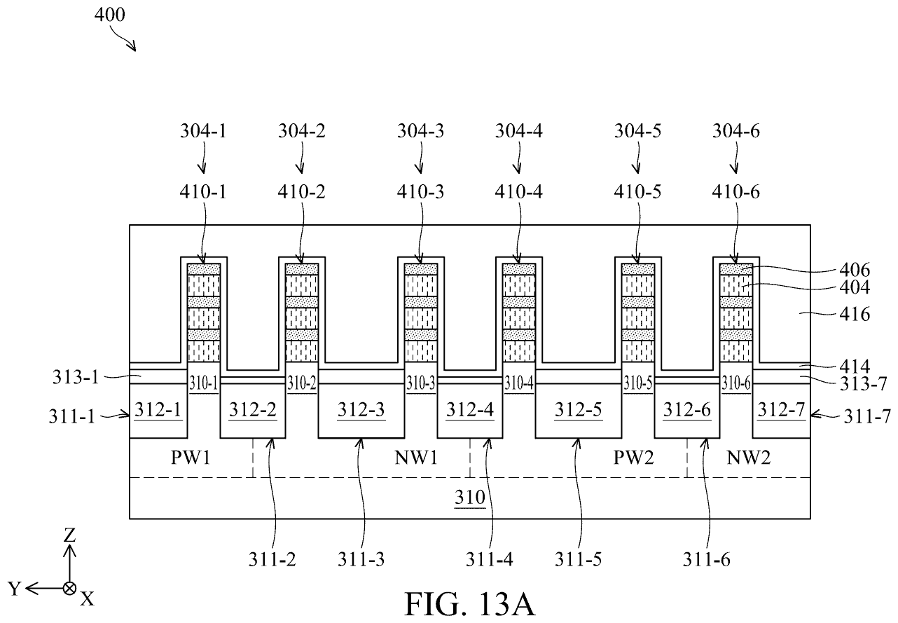

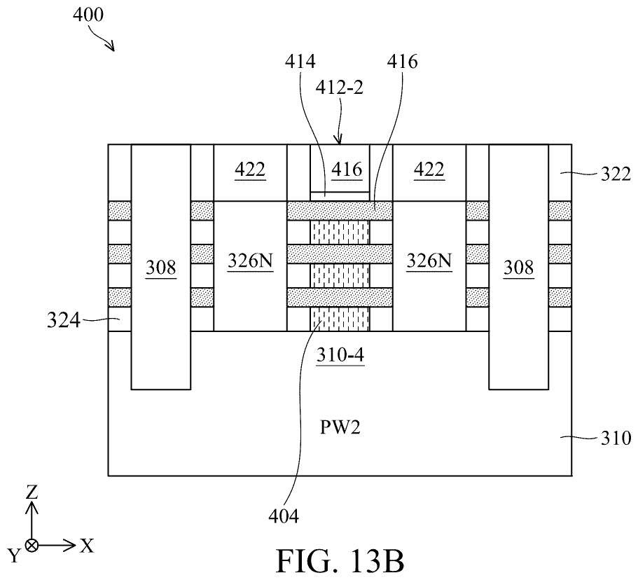

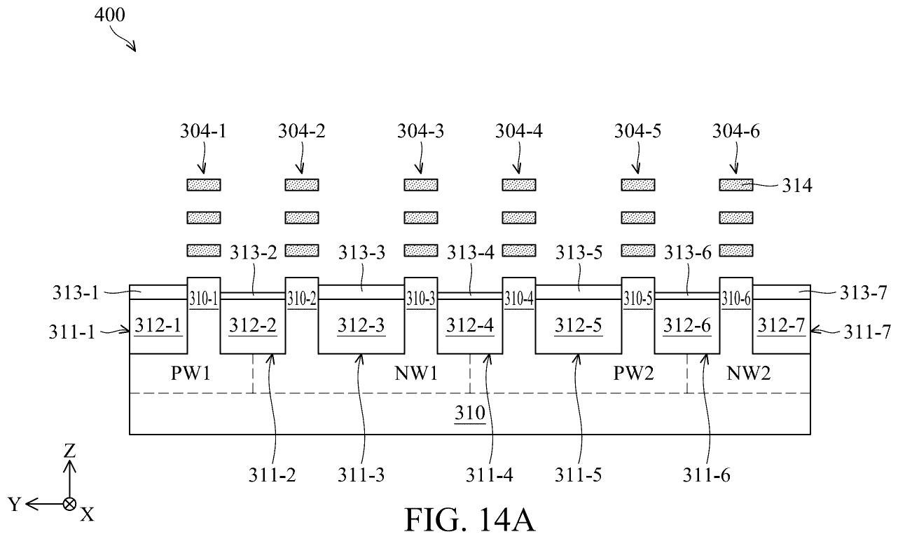

Referring to FIGS. 13A and 13B, the dielectric gate structure 308 discussed above are formed to replace portions of the dummy gate structures 412 and the semiconductor layers 404 and 406. More specifically, the dummy gate structures 412-1, and 412-3 and the semiconductor layers 404 and 406 below the dummy gate structures 412-1 and 412-3 are replaced with dielectric gate structures 308, as shown in FIG. 13B. In order to form the dielectric gate structures 308, one or more lithography and etching processes may be performed to remove the portions of the dummy gate structures 412 (the dummy gate structures 412-1 and 412-3) and the semiconductor layers 404 and 406 in regions to be formed the dielectric gate structures 308, and then the dielectric material for the dielectric gate structures 308 discussed above are formed in the regions to form the dielectric gate structures 308. As shown in FIG. 13B, portions of the substrate 310 in the regions to be formed the dielectric gate structures 308 are removed during the formation of the dielectric gate structures 308. Therefore, top surfaces of the substrate 310 in contact with the dielectric gate structures 308 are lower than other top surfaces of the substrate 310.

Still referring to FIGS. 13A and 13B, the source/drain features 326N/326P discussed above are formed in the source/drain trenches 418. The source/drain features 326N/326P are also formed on opposite sides of the dummy gate structures 412 in the X-direction, as shown in FIG. 13B. One or more epitaxy processes may be employed to grow the source/drain features 326N/326P. Epitaxy processes can implement CVD deposition techniques (for example, vapor-phase epitaxy (VPE), UHVCVD, LPCVD, and/or PECVD), molecular beam epitaxy, other suitable SEG processes, or a combination thereof. One or more annealing processes may be performed to activate the dopants in the source/drain features 326N/326P. The annealing processes may include rapid thermal annealing (RTA) and/or laser annealing processes.

Still referring to FIGS. 13A and 13B, after the formation of the source/drain features 326N/326P, an ILD layer 422 is formed to fill the space between the gate spacers 322. The ILD layer 422 may be formed by PECVD (plasma enhanced CVD), FCVD (flowable CVD), or other suitable methods. In some embodiments, the ILD layer 422 include a dielectric material similar to that of the ILD layer 422 discussed above. Subsequent to the formation of the ILD layer 422, a CMP process and/or other planarization process is performed on the ILD layer 422 until the top surfaces of the dummy gate structures 412 are exposed.

In some embodiments, before the formation of the ILD layer 422, a contact etch stop layer (CESL) may be conformally formed on the sidewalls of the gate spacers 322 and over the top surfaces of the source/drain features 326N/326P. The ILD layer 422 is then formed over and between the CESL to fill the space between the CESL. The CESL includes a material that is different than the ILD layer 422. The CESL may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods.

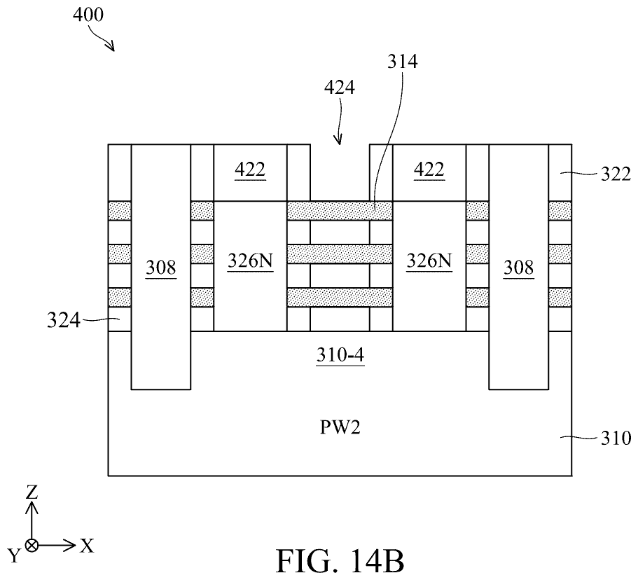

Referring to FIGS. 14A and 14B, the dummy gate structure 412-2 is selectively removed through any suitable lithography and etching processes. In some embodiments, the lithography process may include forming a photoresist layer (resist), exposing the resist to a pattern, performing a post-exposure bake process, and developing the resist to form a masking element, which exposes a region including the dummy gate structure 412-2. Then, the dummy gate structure 412-2 is selectively etched through the masking element. Etch selectivity may be achieved by selecting the appropriate etching chemicals, and the dummy gate structure 412-2 may be removed without substantially affecting the gate spacers 322, the inner spacers 324, and the substrate 310. The removal of the dummy gate structure 412-2 creates a gate trench 424. The gate trench 424 expose the top surfaces of the topmost semiconductor layers 406 underlies the dummy gate structure 412-2.

Still referring to FIGS. 14A and 14B, the semiconductor layers 404 in the fins 410 are selectively removed through the gate trench 424, using a wet or dry etching process for example, so that the semiconductor layers 406 in the fins 410 are exposed in the gate trench 424 to form the nanostructures 314 discussed above. Such a process may also be referred to as a nanostructure release process, a wire release process, a nanowire release process, a nanosheet release process, a nanowire formation process, a nanosheet formation process, or a wire formation process. In some embodiments, the removal of the semiconductor layers 404 causes the exposed semiconductor layers 406 (the nanostructures 314) to be spaced apart from each other in the vertical direction (e.g., in the Z-direction). The exposed semiconductor layers 406 extend longitudinally in the horizontal direction (e.g., in the X-direction), and each connects one source/drain feature 326N/326P to another source/drain feature 326N/326P.

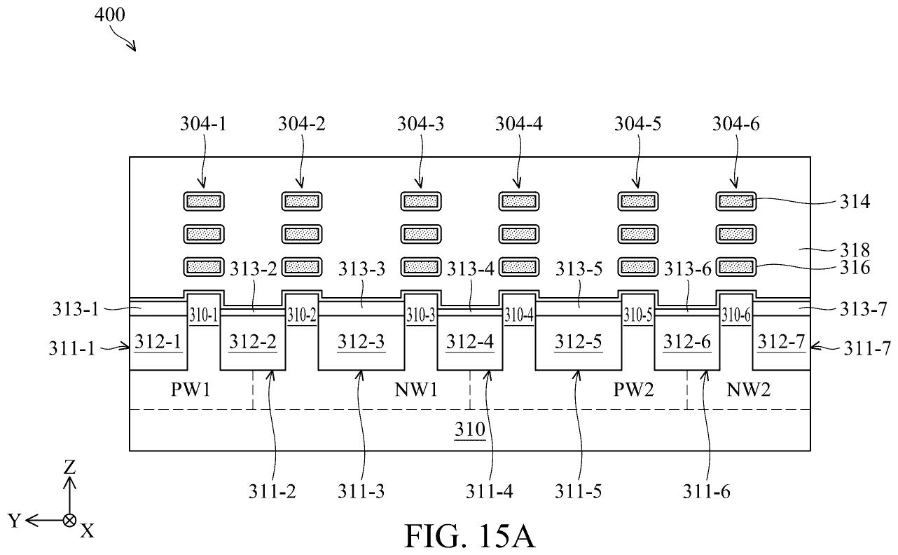

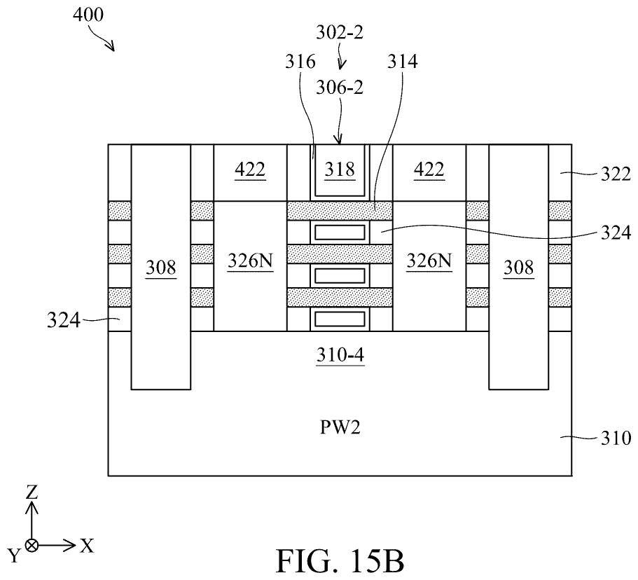

Referring to FIGS. 15A and 15B, a gate structure 426 is formed in the gate trenches 424 to wrap around the semiconductor layers 406 (the nanostructures 314). Similar to the gate structures 306 discussed above, the gate structure 426 includes the gate dielectric layer 316 and the gate electrode layer 318 over the gate dielectric layer 316, as discussed above. In some embodiments, the gate dielectric layers 316 are formed to wrap around each of the semiconductor layers 406 (the nanostructures 314). Additionally, the gate dielectric layers 316 are also formed on sidewalls of the inner spacers 324 and the gate spacers 322.

The gate electrode layer 318 is then formed to fill the remaining spaces of the gate trenches 424, and over the gate dielectric layers 316 in such a way that the gate electrode layer 318 wraps around the semiconductor layers 406 (the nanostructures 314), the gate dielectric layer 316, and the interfacial layers (if present). The gate electrode layer 318, the gate dielectric layers 316, and the interfacial layers (if present) may be collectively called as the gate structures 306 wrapping around the semiconductor layers 406 (the nanostructures 314), as discussed above.

Referring to FIGS. 15A and 15B, the dielectric structures 320 discussed above are formed. As shown in FIG. 15B, the dielectric structures 320 are formed in the gate structure 426 to cut the gate structure 426 into the gate structures 306-1, 306-2, and 306-3 discussed above. As such, the dielectric structures 320 are on opposite sides of the gate structures 306 and the dielectric gate structures 308 in the Y-direction, as discussed above. The dielectric structures 320 also separate the gate structures 306 and/or the dielectric gate structures 308 from gate structures and/or dielectric gate structures of other circuit cells (not shown) in other rows of the semiconductor device 300. In some embodiments, the dielectric structures 320 extend vertically into the isolation structures 311. More specifically, as shown in FIG. 15B, the dielectric structures 320 pass through the dielectric layers 313 of the isolation structures 311 and extend vertically into the oxide layers 312 of the isolation structures 311.

Still referring to FIGS. 15A and 15B, the silicide features 328 and source/drain contacts 330 discussed above are formed over the source/drain features 326N/326P. The silicide features 328 and source/drain contacts 330 are also formed in the ILD layer 422. The cap layer, the ILD 334, the IMD layer 336, the vias VD, and the gate vias VG are formed after the formation of the silicide features 328 and source/drain contacts 330, as shown in FIGS. 4A to 4D. As such, the semiconductor device 300 of the circuit cells 302-1 to 302-3 discussed above is completed.

The embodiments disclosed herein relate to semiconductor structures, and more particularly to semiconductor devices comprising different active area spaces and different isolation structure thicknesses for circuit cells. Furthermore, the present embodiments provide one or more of the following advantages. The active area space in one circuit cell is smaller for reducing the width of the gate structure in the longitudinal direction, which reduces the gate-to-contact parasitic capacitance. The active area space in different circuit cells is larger to have a larger process window for the dielectric structure between the gate structures and to reduce the gate-to-gate parasitic capacitance. Furthermore, the smaller isolation structure thickness between the active area spaces in one circuit cell has larger process window in release process and the larger isolation structure thickness between the active area spaces in different circuit cells reduces the contact area between the gate structures and the base fins, such that the process margin and performance are improved.

Thus, one of the embodiments of the present disclosure describes a semiconductor device that includes a first circuit cell, a first dielectric layer, a second dielectric layer, and a third dielectric layer. The first circuit cell includes a first active area in a first well in a substrate, a second active area in a second well in the substrate, and a first gate structure wrapping around nanostructures in the first active area and the second active area. The first well has a first doping type and the second well has a second doping type different to the first doping type. The first dielectric layer is over the first well. The second dielectric layer is over the first well and the second well. The third dielectric layer is over the second well. The first dielectric layer, the second dielectric layer, and the third dielectric layer are under and in contact with the first gate structure. A thickness of the second dielectric layer is less than thicknesses of the first dielectric layer and the third dielectric layer.

In another of the embodiments, discussed is a semiconductor device including a first active area and a second active area, a third active area and a fourth active area, a first gate structure, a second gate structure, a third gate structure, a first nitrogen content dielectric layer, a second nitrogen content dielectric layer, and a third nitrogen content dielectric layer. The first active area and the second active area extend in a first direction and in a first well in a substrate. The third active area and the fourth active area extend in the first direction and in a second well in the substrate. The first well and the second well have different doping types. The first gate structure extends in a second direction and wraps around nanostructures in the first active area. The second direction is perpendicular to the first direction. The second gate structure extends in the second direction and wraps around nanostructures in the second active area and the third active area. The third gate structure extends in the second direction and wraps around nanostructures in the fourth active area. The first nitrogen content dielectric layer has a first thickness, is under the first gate structure and the second gate structure, and is between the first active area and the second active area. The second nitrogen content dielectric layer has a second thickness, is under the second gate structure, and is between the second active area and the third active area. The third nitrogen content dielectric layer has a third thickness, is under the second gate structure, and is between the second active area and the third active area. A ratio of the first thickness to the second thickness and a ratio of the third thickness to the second thickness are in a range from 1.1 to 1.4. A space between the second active area and the third active area is less than a space between the first active area and the second active area and a space between the third active area and the fourth active area.

In yet another of the embodiments, discussed is a semiconductor device that includes a first circuit cell, a second circuit cell, a third circuit cell, a first isolation structure, a second isolation structure, and a third isolation structure. The first circuit cell, the second circuit cell, and the third circuit cell are arranged in a first direction. The first circuit cell includes a first active area in a first doping type well in a substrate and a first gate structure engaging the first active area. The second circuit cell includes a second active area in the first doping type well, a third active area in a second doping type well in the substrate, and a second gate structure engaging the second active area and the third active area. The third circuit cell includes a fourth active area in a first doping type well and a third gate structure engaging the fourth active area. The first isolation structure is over the first doping type well. The second isolation structure is over the first doping type well and the second doping type well. The third isolation structure is over the second doping type well. A thickness of the second isolation structure is less than thicknesses of the first isolation structure and the third isolation structure. Each of the first active area, the second active area, the third active area, and the fourth active area includes a base fin protruded from the substrate and nanostructure over the base fin. A distance from a bottom surface of the second gate structure over the second isolation structure to a top surface of the base fins is greater than a distance from a bottom surface of the second gate structure over the first isolation structure to the top surface of the base fins.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first circuit cell, comprising:
a first active area in a first well in a substrate;
a second active area in a second well in the substrate, wherein the first well has a first doping type and the second well has a second doping type different to the first doping type; and
a first gate structure wrapping around nanostructures in the first active area and the second active area;
a first dielectric layer over the first well;
a second dielectric layer over the first well and the second well; and
a third dielectric layer over the second well,
wherein the first dielectric layer, the second dielectric layer, and the third dielectric layer are under and in contact with the first gate structure,
wherein a thickness of the second dielectric layer is less than thicknesses of the first dielectric layer and the third dielectric layer.

2. The semiconductor device of claim 1, wherein a ratio of the thickness of the first dielectric layer to the thickness of the second dielectric layer and a ratio of the thickness of the dielectric layer to the thickness of the second dielectric layer are in a range from 1.1 to 1.4.

3. The semiconductor device of claim 1, further comprising:
a second circuit cell, comprising:
a third active area in a third well in the substrate, wherein the third well has the second doping type;
a fourth active area in the first well; and
a second gate structure wrapping around nanostructures in the third active area and the fourth active area;
a third circuit cell, comprising:
a fifth active area in the second well;
a sixth active area in a fourth well in the substrate, wherein the fourth well has the first doping type; and
a third gate structure wrapping around nanostructures in the fifth active area and the sixth active area,
wherein a first space between the first active area and the second active area is less than a second space between the fourth active area and the first active area and a third space between the second active area and the fifth active area.

4. The semiconductor device of claim 3, wherein a ratio of the second space to the first space and a ratio of the third space to the first space are in a range from 1.1 to 2.

5. The semiconductor device of claim 1, wherein a first bottom surface of the first gate structure in contact with the second dielectric layer is lower than a second bottom surface of the first gate structure in contact with the first dielectric layer and a third bottom surface the first gate structure in contact with the third dielectric layer.

6. The semiconductor device of claim 5,
wherein each of the first active area and the second active area comprises a base fin protruded from the substrate,
wherein a ratio of a distance from the second bottom surface to top surfaces of the base fins to a distance from the first bottom surface to the top surface of the base fins is in a range from 1.1 to 3.

7. The semiconductor device of claim 1, wherein the first dielectric layer, the second dielectric layer, and the third dielectric layer are silicon nitride layers.

8. The semiconductor device of claim 1, further comprising:
first source/drain features in source/drain regions of the first active area and on opposite sides of the first gate structure;
second source/drain features in source/drain regions of the second active area and on opposite sides of the first gate structure; and
first bottom dielectric layers under the first source/drain features.

9. The semiconductor device of claim 8, further comprising:
second bottom dielectric layers under the second source/drain features.

10. The semiconductor device of claim 8, wherein the second source/drain features are in contact with the substrate.

11. A semiconductor device, comprising:
a first active area and a second active area extending in a first direction and in a first well in a substrate;
a third active area and a fourth active area extending in the first direction and in a second well in the substrate, wherein the first well and the second well have different doping types;
a first gate structure extending in a second direction and wrapping around nanostructures in the first active area, wherein the second direction is perpendicular to the first direction;
a second gate structure extending in the second direction and wrapping around nanostructures in the second active area and the third active area;
a third gate structure extending in the second direction and wrapping around nanostructures in the fourth active area;
a first nitrogen content dielectric layer having a first thickness, under the first gate structure and the second gate structure, and between the first active area and the second active area;
a second nitrogen content dielectric layer having a second thickness, under the second gate structure, and between the second active area and the third active area; and
a third nitrogen content dielectric layer having a third thickness, under the second gate structure, and between the second active area and the third active area,
wherein a ratio of the first thickness to the second thickness and a ratio of the third thickness to the second thickness are in a range from 1.1 to 1.4,
wherein a space between the second active area and the third active area is less than a space between the first active area and the second active area and a space between the third active area and the fourth active area.

12. The semiconductor device of claim 11, wherein a ratio of the space between the first active area and the second active area to the space between the second active area and the third active area is in a range from 1.1 to 2.

13. The semiconductor device of claim 11, further comprising:
a first dielectric structure between the first gate structure and the second gate structure, and passing through the first nitrogen content dielectric layer; and
a second dielectric structure between the second gate structure and the third gate structure, and passing through the third nitrogen content dielectric layer.

14. The semiconductor device of claim 13, wherein each of the second active area and the third active area comprises a base fin protruded from the substrate,
wherein a fourth thickness of a first portion of the second gate structure lower top surfaces of the base fins and between the second active area and the third active area is greater than a fifth thickness of a second portion of the second gate structure lower the top surfaces of the base fins and between the first dielectric structure and the second active area.

15. The semiconductor device of claim 14, wherein a ratio of the fourth thickness to the fifth thickness is in a range from 1.1 to 3.

16. The semiconductor device of claim 11, wherein the first nitrogen content dielectric layer, the second nitrogen content dielectric layer, and the third nitrogen content dielectric layer comprise Si₃N₄, SiON, SiOCN, or combinations thereof.

17. A semiconductor device, comprising:
a first circuit cell, a second circuit cell, and a third circuit cell arranged in a first direction,
wherein the first circuit cell comprises:
a first active area in a first doping type well in a substrate; and
a first gate structure engaging the first active area,
wherein the second circuit cell comprises:
a second active area in the first doping type well;
a third active area in a second doping type well in the substrate; and
a second gate structure engaging the second active area and the third active area,
wherein the third circuit cell comprises:
a fourth active area in a first doping type well; and
a third gate structure engaging the fourth active area,
a first isolation structure over the first doping type well;
a second isolation structure over the first doping type well and the second doping type well; and
a third isolation structure over the second doping type well,
wherein a thickness of the second isolation structure is less than thicknesses of the first isolation structure and the third isolation structure,
wherein each of the first active area, the second active area, the third active area, and the fourth active area comprises a base fin protruded from the substrate and nanostructures over the base fin,
where a distance from a bottom surface of the second gate structure over the second isolation structure to a top surface of the base fins is greater than a distance from a bottom surface of the second gate structure over the first isolation structure to the top surface of the base fins.

18. The semiconductor device of claim 17, wherein each of the first isolation structure, the second isolation structure, and the third isolation structure comprises an oxide layer and a dielectric layer having nitrogen over the oxide layer.

19. The semiconductor device of claim 17, wherein thicknesses of the oxide layers of the first isolation structure, the second isolation structure, and the third isolation structure are the same,
wherein a first thickness of the dielectric layer of the second isolation structure is less than a second thickness of the dielectric layer of the first isolation structure.

20. The semiconductor device of claim 19, wherein a ratio of the first thickness to the second thickness is in a range from 1.1 to 1.4.
